(19) United States
(12) Patent Application Publication
(10) Pub. No.: US 2026/0143784 A1
(43) Pub. Date: May 21, 2026

(54) SOURCE/DRAIN EPITAXY VOID IMPROVEMENT IN NANOSHEET TRANSISTORS WITH WIDE SHEET WIDTHS

(71) Applicant: Taiwan Semiconductor Manufacturing Co., Ltd., Hsinchu (TW)

(72) Inventors: Jung-Hung CHANG, Hsinchu (TW); Tsung-Han CHUANG, Hsinchu (TW); Shih-Cheng CHEN, Hsinchu (TW); Wen-Ting LAN, Hsinchu (TW); Kuo-Cheng CHIANG, Hsinchu (TW); Chih-Hao WANG, Hsinchu (TW); Fu-Cheng CHANG, Hsinchu (TW)

(73) Assignee: Taiwan Semiconductor Manufacturing Co., Ltd., Hsinchu (TW)

(21) Appl. No.: 19/092,946

(22) Filed: Mar. 27, 2025

Related U.S. Application Data
(60) Provisional application No. 63/721,327, filed on Nov. 15, 2024.

(51) Int. Cl. H10D 84/01; H10D 30/00; H10D 62/40; H10D 64/01; H10D 84/83

(52) U.S. Cl. CPC H10D 84/013; H10D 30/507; H10D 62/405; H10D 64/017; H10D 84/832

(57) ABSTRACT

A method for forming a semiconductor device is provided. The method includes forming, over a top surface of a substrate with a (110) crystal orientation, a plurality of fin structures each comprising alternating channel semiconductor portions and sacrificial dielectric portions, wherein sidewalls of the channel semiconductor portions of adjacent fin structures in the plurality of fin structures of each of the adjacent fin structures are exposed by a source/drain trench, wherein top, sidewall and bottom surfaces of the channel semiconductor portions of the adjacent fin structures have the (110) crystal orientation. The method further includes depositing an epitaxial semiconductor region at a bottom of the source/drain trench, forming a bottom dielectric feature over the epitaxial semiconductor region, and epitaxially growing a source/drain feature from the sidewall surfaces of the channel semiconductor portions of the adjacent fin structures to fill the source/drain trench.

### PRIORITY CLAIM AND CROSS-REFERENCE

This application claims the benefit of U.S. Provisional Ser. No. 63/721,327 filed Nov. 15, 2024, which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for fabricating a gate-all-around (GAA) device, in accordance with some embodiments of the present disclosure.

FIGS. 2-19 illustrate various views of the GAA device during a fabrication process according to the method of FIG. 1, in accordance with some embodiments of the present disclosure.

FIG. 20 is a flowchart of a method for fabricating a GAA device, in accordance with some embodiments of the present disclosure.

FIGS. 21-35B illustrate various views of the GAA device during a fabrication process according to the method of FIG. 20, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Non-planar transistor architectures, such as nanosheet field-effect transistors (FETs), utilize semiconductor nanosheet channels with gate-all-around (GAA) technologies to enhance device density, power efficiency, and performance compared to fin-type FETs. In nanosheet FETs, the gate structure fully encloses each nanosheet, enabling better channel depletion, reducing short-channel effects through steeper subthreshold swing (SS), and minimizing drain-induced barrier lowering (DIBL). Additionally, the wrap-around gate structures and source/drain contacts in nanosheet FETs improve control over leakage current and parasitic capacitance, even as drive currents increase.

In a GAA configuration, a nanosheet FET includes a source feature, a drain feature, and vertically stacked and spaced nanosheet channels between the source and drain features. A gate surrounds the nanosheet channels and regulates electron flow through the nanosheet channels between the source and drain features. GAA nanosheet FETs are fabricated by forming alternating layers of channel nanosheets and sacrificial nanosheets. The sacrificial nanosheets are released from the channel nanosheets before the FET device is finalized.

Nanosheet device architectures allow for varying sheet widths to suit different applications. Wider sheets support higher-speed performance by accommodating greater current density, whereas narrower sheets are more suitable for low-power applications due to enhanced gate control. For instance, wide channel regions enable higher current density to boost performance, while narrow channel regions provide superior gate control for improved power efficiency. In modern logic devices with a GAA structure, in-situ doped semiconductor material is selectively grown on recessed source/drain (S/D) regions to form source/drain features through a selective epitaxial growth process. However, wider nanosheets designed for high-performance computing are more prone to epitaxy void formation. These voids typically occur when the semiconductor material grown from the nanosheets merges at the ends or tops during the selective epitaxial growth process. Such voids can negatively impact device performance. Therefore, developing effective strategies to prevent the epitaxy void formation in source/drain features of wider nanosheet FETs is needed.

In embodiments of the present disclosure, source/drain epitaxy void formation is mitigated through a synergic approach. This includes implementing a gate protection top (GPT) scheme to prevent early merging at the tops of sheets, utilizing a semiconductor substrate with a (110) surface crystal orientation for nanosheet formation to avoid early merging at the sheet ends, and combining the (110) surface crystal orientation with continuous and conformal selective epitaxy deposition techniques during source/drain formation. As a result, device reliability and performance can be improved.

The GAA transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structures.

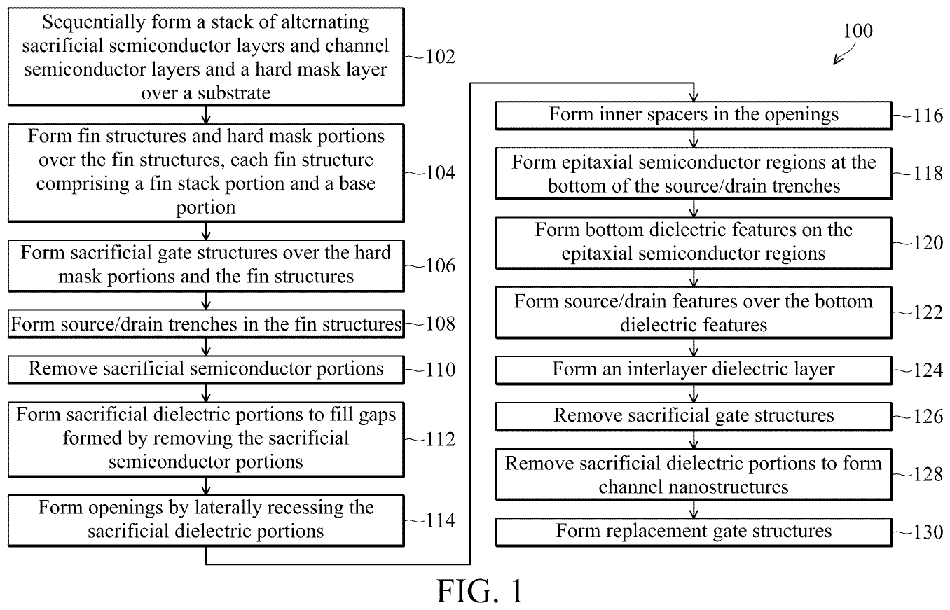

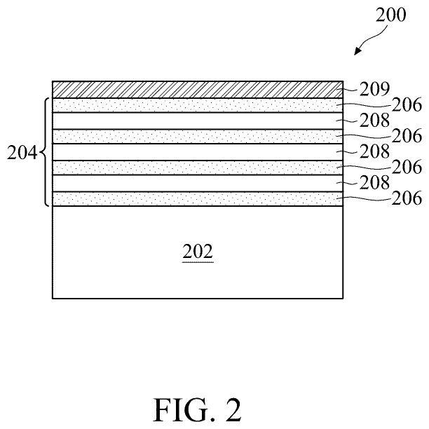

FIG. 1 is a flowchart of a method 100 of forming a GAA device 200, in accordance with some embodiments of the present disclosure. FIGS. 2-19 are various views of the GAA device 200 at various stages of the method 100, in accordance with some embodiments. Some embodiments of method 100 are described below in conjunction with FIGS. 2-19 with reference to the GAA device 200. The method 100 is merely an example and is not intended to limit the present disclosure beyond what is explicitly recited in the claims. Additional operations can be provided before, during, and after the method 100, and some operations described can be replaced, eliminated, or moved around for additional embodiments of the method.

Referring to FIGS. 1 and 2, the method 100 includes operation 102, where an initial structure of the GAA device 200 is provided. The initial structure includes a substrate 202, a stack 204 of alternating epitaxial semiconductor layers over the substrate 202, and a hard mask layer 209 over the stack 204. FIG. 2 is a cross-sectional view of the GAA device 200 after forming the stack 204 of the alternating epitaxial semiconductor layers over the substrate 202 followed by forming the hard mask layer 209 over the stack 204.

The substrate 202 can be any suitable substrate with a (110) surface crystal orientation, and can be processed with various features. In some embodiments, the substrate 202 may be a semiconductor substrate, such as a silicon substrate. In some embodiments, the substrate 202 includes various layers, including conductive or insulating layers formed on a semiconductor substrate. The substrate 202 may include various doping configurations. For example, different doping profiles (e.g., n wells, p wells) may be formed on the substrate 202 in regions designed for different device types (e.g., n-type FETs, p-type FETs). Suitable doping may include ion implantation of dopants and/or diffusion processes. The substrate 202 typically has isolation features (e.g., shallow trench isolation (STI) features) interposing the regions providing different device types. The substrate 202 includes other semiconductors such as germanium or diamond. Alternatively, the substrate 202 includes a compound semiconductor such as silicon carbide (SiC), gallium arsenic, gallium phosphide, indium phosphide, indium arsenide, indium antimonide; an alloy semiconductor, such as SiGe, GaAsP, AlInAs, AlGaAs, GalnAs, GaInP, GaInAsP, and/or other suitable materials. Further, the substrate 202 may optionally include an epitaxial layer, may be strained for performance enhancement, may include a silicon-on-insulator structure, and/or may have other suitable enhancement features.

The stack 204 of alternating epitaxial semiconductor layers are blanketly deposited on the substrate 202. The stack 204 comprises alternating sacrificial semiconductor layers 206 and channel semiconductor layers 208 with the sacrificial semiconductor layers 206 being the topmost layer. In some embodiments, the sacrificial semiconductor layers 206 include a first semiconductor material, and the channel semiconductor layers 208 include a second semiconductor material that is different from the first semiconductor material. The materials of sacrificial semiconductor layers 206 and channel semiconductor layers 208 may be chosen based on providing different etching selectivities. For example, in some embodiments, the first semiconductor material may comprise germanium (Ge) or silicon germanium (SiGe), whereas the second semiconductor material may comprise silicon (Si). In some alternative embodiments, the first semiconductor material includes SiGe having a first Ge content, and the second semiconductor material includes SiGe having a second Ge content lower than the first Ge content. In various embodiments, the sacrificial semiconductor layers 206 and the channel semiconductor layer 208 are substantially dopant-free (i.e., having an extrinsic dopant concentration less than about 1×10¹⁷ cm⁻³).

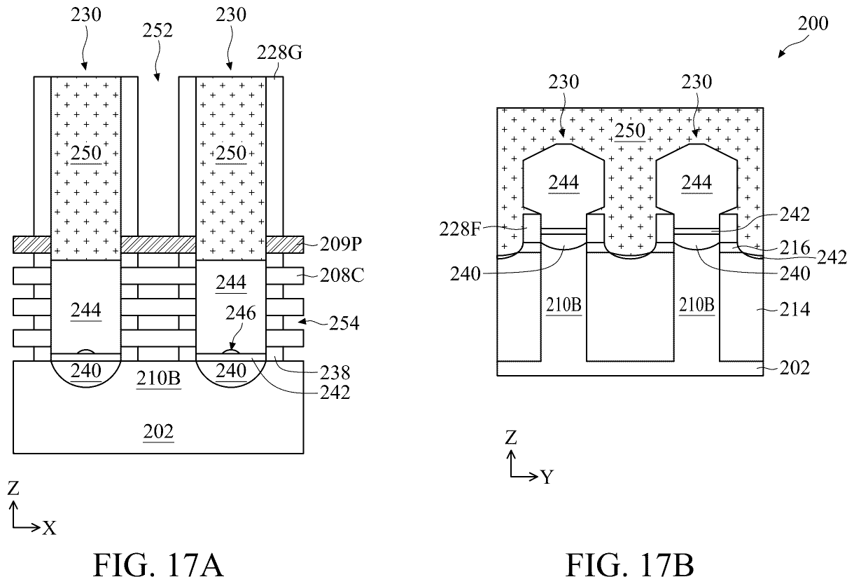

In some embodiments, the sacrificial semiconductor layers 206 may be removed in a later process, thereby leaving the channel semiconductor layers 208, which define channel nanostructures (e.g., 208C of FIG. 17A) for the GAA device 200. The thickness of sacrificial semiconductor layers 206 thus determines the spacing between adjacent channel nanostructures (e.g., 208C of FIG. 17A). In some embodiments, the thickness of sacrificial semiconductor layers 206 may range from about 8 nm to about 15 nm. The thickness of the channel semiconductor layers 208 is chosen based on, for example, manufacturing considerations, transistor performance considerations, and the like. In some embodiments, the thickness of the channel semiconductor layers 208 may range from about 4 nm to about 10 nm.

The number of sacrificial semiconductor layers 206 and channel semiconductor layers 208 depends on the desired number of channel nanostructures (e.g., 208C of FIG. 17A) in the GAA device 200. In some embodiments, the number of channel semiconductor layers 208 is from, for example, 2 to 10, to form a stack of 2 to 10 vertically separated channel nanostructures. In some embodiments and as illustrated in FIG. 2, the stack 204 includes four (4) layers of sacrificial semiconductor layers 206 and three (3) layers of channel semiconductor layers 208.

The sacrificial semiconductor layers 206 and channel semiconductor layers 208 are epitaxially grown layer-by-layer from a top surface of the substrate 202. In some embodiments, the sacrificial semiconductor layers 206 and channel semiconductor layers 208 are grown by a molecular beam epitaxy (MBE) process, a chemical vapor deposition (CVD) process such as a metal organic CVD (MOCVD) process, or other suitable epitaxy growth processes. The epitaxy growth results in the sacrificial semiconductor layers 206 and the channel semiconductor layers 208 having the same crystal orientation as the substrate 202. In some embodiments, when the substrate 202 has a (110) surface crystal orientation, the sacrificial semiconductor layers 206 and the channel semiconductor layers 208 also exhibit a (110) surface crystal orientation.

The hard mask layer 209 is formed over the topmost surface of the stack 204. In some embodiments, the hard mask layer 209 includes a dielectric material such as, for example, silicon nitride (SiN), silicon carbon nitride (SiCN), silicon oxycarbide (SiOC), silicon oxycarbon nitride (SiOCN), or a combination thereof. In some embodiments, the hard mask layer 209 is formed by CVD, plasma-enhanced CVD (PECVD), physical vapor deposition (PVD), atomic layer deposition (ALD), or other suitable deposition processes. In some embodiments, the hard mask layer 209 may have a double-layer structure including a pad oxide layer and a pad nitride layer formed over the pad oxide layer. In some embodiments, the pad oxide layer includes silicon oxide, which can be formed by thermal oxidation. The pad nitride layer includes SiN, which can be formed by CVD, PECVD, PVD, ALD, or other suitable deposition processes. The hard mask layer 209 is used to protect portions of the substrate 202 and the stack 204 and is used to define a pattern (e.g., fins) as described below.

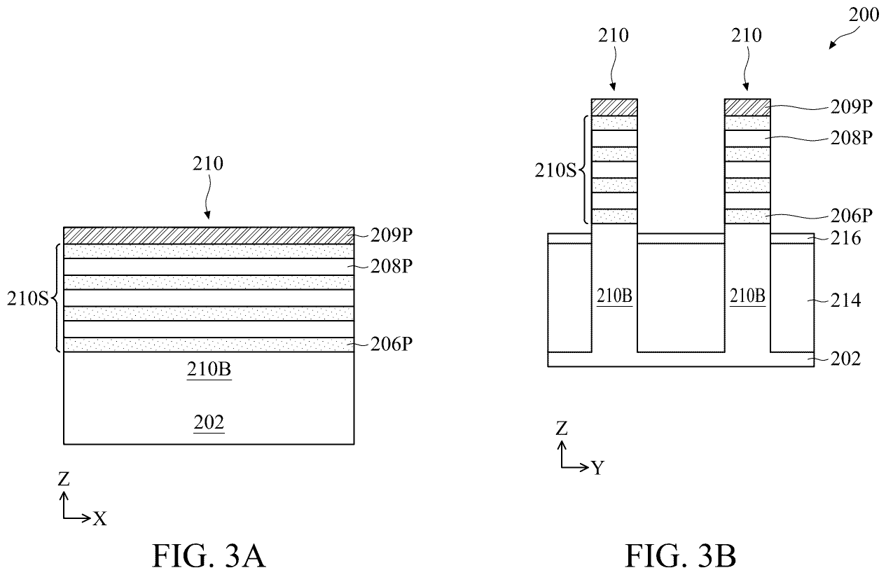

Referring to FIGS. 1 and 3A-3B, the method 100 proceeds to operation 104, where fin structures 210 are formed from the stack 204, in accordance with some embodiments. FIGS. 3A and 3B are cross-sectional views of the GAA device 200 after forming the fin structures 210. It should be noted that although two fin structures 210 are illustrated in FIG. 3B, any number of fin structures 210 may be formed.

In some embodiments, the stack 204 and a portion of the substrate 202 are patterned to form the fin structures 210. Each fin structure 210 extends vertically along the Z direction from the substrate 202 and has a length dimension along the X direction and a width dimension along the Y direction. The width of each fin structure 210 may range from about 10 nm to about 90 nm. Each fin structure 210 includes a base portion 210B and a fin stack portion 210S. The base portion 210B is formed from the substrate 202, while the fin stack portion 210S is formed from the stack 204 and includes portions of the sacrificial semiconductor layers 206 (herein referred to as sacrificial semiconductor portions 206P) and portions of the channel semiconductor layers 208 (herein referred to as channel semiconductor portions 208P).

In some embodiments, the fin structures 210 may be formed using photolithography and etch processes. During a photolithography process, a photoresist layer is first applied to the hard mask layer 209 by, for example, spin coating. Then, the photoresist layer is exposed according to a mask of patterns, and is developed to form the patterns in the photoresist layer. The photoresist layer with the patterns can be used as an etch mask to pattern other layers. In some embodiments, patterning the photoresist layer is performed using an extreme ultraviolet (EUV) light lithography process. The patterned photoresist layer is then used to protect regions of the substrate 202 and the sacrificial semiconductor layers 206 and channel semiconductor layers 208 formed thereupon, while an etching process forms the fin structures 210. In some embodiments, the etching process may be a dry etching process such as plasma etching or reactive ion etching (RIE), a wet etching process, or a combination thereof.

In various other embodiments, the fin structures 210 may be formed using suitable processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Mandrels are formed alongside the patterned sacrificial layer using a self-aligned process. The sacrificial layer is then removed, and the remaining mandrels are then used as an etch mask to pattern the stack 204 and the substrate 202 to provide the fin structures 210.

Subsequently, an isolation feature 214 may be formed over the substrate 202 and on opposite sides of the fin structures 210. In some embodiments, the isolation feature 214 may include silicon oxide, silicon nitride, silicon oxynitride, silicon carbonitride, silicon oxycarbonitride fluorine-doped silicate glass (FSG), a low-k dielectric, and/or other suitable dielectric materials. In an example process, the isolation feature 214 may be formed by first depositing a dielectric layer over the substrate 202, filling the trenches between the fin structures 210. In various examples, the dielectric layer may be deposited by a CVD process, a subatmospheric CVD (SACVD) process, a flowable CVD process, an atomic layer deposition (ALD) process, a physical vapor deposition (PVD) process, spin-on coating, and/or other suitable process. The deposited dielectric material is then planarized, for example, by a chemical mechanical polishing (CMP) process. The planarized dielectric layer is further recessed using a suitable anisotropic etching process to expose the fin stack portions 210S of the fin structures 210. In some embodiments, the anisotropic etching process is a dry etching process, a wet etching process, and/or a combination thereof. In some embodiments and as shown in FIG. 3B, a top surface of isolation feature 214 is lower than a bottom surface of the lowermost sacrificial semiconductor portions 206P, so that the fin stack portion 210S rises above the isolation feature 214.

Next, an etch stop layer 216 may be formed over the isolation feature 214. The etch stop layer 216 includes a dielectric material different from that of the isolation feature 214. In some embodiments, the etch stop layer 216 may include silicon oxide, silicon nitride, a combination thereof, or the like. In some embodiments, the etch stop layer 216 may be formed by first depositing a dielectric material over the isolation feature 214 and fin structures 210 and recessing the deposited dielectric material by an anisotropic etch.

As shown in FIGS. 3A and 3B, the hard mask layer 209 is formed from a dielectric material having a high etching selectivity compared to the isolation feature 214 and the etch stop layer 216, and remains in the structure after the formation of the isolation feature 214 and the etch stop layer 216. The remaining portions of the hard mask layer 209 are referred to as hard mask portions 209P.

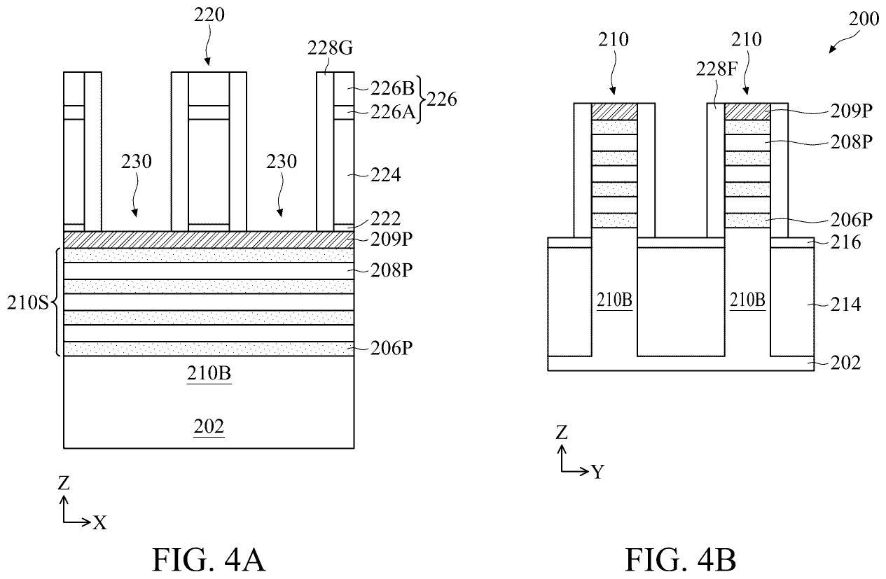

Referring to FIGS. 1 and 4A-4B, the method 100 proceeds to operation 106, where sacrificial gate structures 220 are formed over the hard mask portions 209P, fin structures 210, and the etch stop layer 216, in accordance with some embodiments. FIGS. 4A and 4B are cross-sectional views of the GAA device 200 after forming the sacrificial gate structures 220.

The sacrificial gate structures 220 extend lengthwise in parallel to each other and are spaced from one another by a distance ranging from about 10 nm to 25 nm. In some embodiments and as shown in FIG. 4A, each of the sacrificial gate structures 220 wraps around the hard mask portions 209P and the fin structures 210, along the sidewalls of the hard mask portions 209P and the fin structures 210 and over the top surfaces of the hard mask portions 209P. The sacrificial gate structure 220 serves as a placeholder and will be replaced with a metal gate structure.

In some embodiments, each of the sacrificial gate structures 220 may include, from bottom to top, a sacrificial gate dielectric 222, a sacrificial gate electrode 224, and a mask 226. In some embodiments, the sacrificial gate dielectric 222 may include silicon oxide, silicon nitride, or silicon oxynitride. The sacrificial gate electrode 224 may include silicon such as polycrystalline silicon or amorphous silicon. The mask 226 may include silicon nitride, silicon oxynitride. In the illustrated embodiment, the mask 226 includes a first mask 226A and a second mask 226B. The first and second masks 226A and 226B include dielectric materials different from each other. In some embodiments, the first mask 226A may include silicon oxide, and the second mask 226B may include silicon nitride.

In some embodiments, the sacrificial gate structures 220 may be formed by first conformally depositing a sacrificial gate dielectric layer over the hard mask portions 209P, the fin structures 210, and the etch stop layer 216. The sacrificial gate dielectric layer may be deposited by CVD, PECVD, ALD, or other suitable conformal deposition processes. The thickness of the sacrificial gate dielectric layer may range from about 1 nm to about 5 nm in some embodiments. A sacrificial gate electrode layer is then blanketly deposited on the sacrificial gate dielectric layer such that the hard mask portions 209P and the fin structures 210 are fully embedded in the sacrificial gate electrode layer. The sacrificial gate electrode layer may be deposited using CVD, PECVD, PVD, ALD, or other suitable deposition processes. The thickness of the sacrificial gate electrode layer may range from about 100 nm to about 200 nm in some embodiments. In some embodiments, the sacrificial gate electrode layer is subjected to a planarization operation after deposition. Subsequently, the first and second mask layers are sequentially deposited over the sacrificial gate electrode layer using, for example, CVD, PECVD, or PVD. Subsequently, the first and second mask layers, the sacrificial gate electrode layer, and the sacrificial gate dielectric layer are patterned using photolithography and etching processes. For example, a photoresist layer (not shown) is applied over the second mask layer and lithographically patterned by lithographic exposure and development. The pattern in the photoresist layer is sequentially transferred into the first mask layer, the second mask layer, the sacrificial gate electrode layer, and the sacrificial gate dielectric layer by at least one anisotropic etching process, thereby forming the sacrificial gate structures 220, which comprises the remaining portions of the first mask layer, the second mask layer, the sacrificial gate electrode layer, and the sacrificial gate dielectric layer. The anisotropic etching process may be a dry etching process, for example, RIE, a wet etching process, or a combination thereof. If not completely consumed, the remaining photoresist layer after formation of the sacrificial gate structures 220 is removed by, for example, ashing.

Next, a sidewall spacer layer is deposited on exposed surfaces of the GAA device 200 by a conformal deposition process, such as, for example, ALD or CVD. The sidewall spacer layer may include a dielectric material such as, for example, an oxide, a nitride, an oxynitride, or combinations thereof. In some embodiments, the sidewall spacer layer is made of silicon nitride. In some embodiments, after deposition, an anisotropic etching process may be performed to remove the sidewall spacer layer from horizontal surfaces, such that the sidewall spacer layer is positioned on the sidewalls of the sacrificial gate structures 220 and the fin structures 210. In other embodiments, the sidewall spacer layer may remain on horizontal surfaces of the sacrificial gate structures 220 and the fin structures 210 until the fin structures 210 are etched back. After removing horizontal portions of the sidewall spacer layer, gate sidewall spacers 228G are formed on sidewalls of the sacrificial gate structures 220 as shown in FIG. 4A, and fin sidewall spacers 228F are formed on sidewall of the fin structures 210 as shown in FIG. 4B.

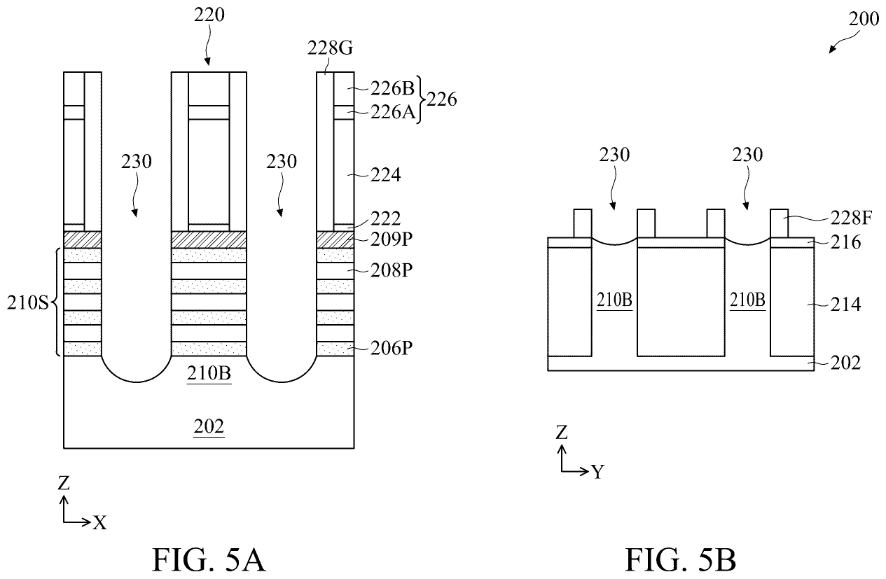

Referring to FIGS. 1 and 5A-5B, the method 100 proceeds to operation 108, where source/drain trenches 230 are formed in the fin structures 210, in accordance with some embodiments. FIGS. 5A and 5B are cross-sectional views of the GAA device 200 after forming the source/drain trenches 230.

The source/drain trenches 230 may extend through the fin stack portion 210S. In some embodiments, the hard mask portion 209P, the sacrificial semiconductor portions 206P, and the channel semiconductor portions 208P in the source/drain regions, or regions not covered by the sacrificial gate structures 220 and gate sidewall spacers 228G, are etched using the sacrificial gate structures 220 and the gate sidewall spacers 228G as an etch mask to form the source/drain trenches 230. The etching may be performed by a dry etching process such as plasma etching or RIE. An example dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Alternatively, the etching may be performed by a wet etching process that uses an etchant such as a mixture of ammonium hydroxide, hydrogen peroxide, and water (APM), tetramethylammonium hydroxide (TMAH), or ammonium hydroxide (NH₄OH). As shown in FIG. 5A, sidewalls of the hard mask portions 209P, the sacrificial semiconductor portions 206P, and the channel semiconductor portions 208P are exposed in the source/drain trenches 230. In some embodiments, the base portions 210B may also be partially etched, so that the source/drain trenches 230 extend into the base portion 210B. Accordingly, the bottom surfaces of the source/drain trenches 230 may be leveled with the top surface of the base portion 210B or lower than the top surface of the base portion 210B. In some embodiments, the portion of the fin stack portion 210S of each fin structure 210 between the sacrificial gate structure 220 is completely removed, exposing the base portion 210B of each fin structure 210.

As shown in FIG. 5B, the fin sidewall spacers 228F are also at least partially recessed. In some embodiments, the fins sidewall spacers 228F may be recessed during etch of the fin structures 210. In other embodiments, the fin sidewall spacers 228F may be removed using a separate process. In some embodiments, heights of the fins sidewall spacers 228F may be controlled to achieve the desired shape of the source/drain features to be formed from the fin structures 210. For example, the heights of the fin sidewall spacers 228F, along the z-direction, from the topmost surface of the isolation feature 214 may be controlled to define critical dimension and/or shape of the source/drain features to be formed. In some embodiments, the heights of the fin sidewall spacers 228F may be set to control the location of the merge point between the two source/drain features formed from the neighboring fin structures 210.

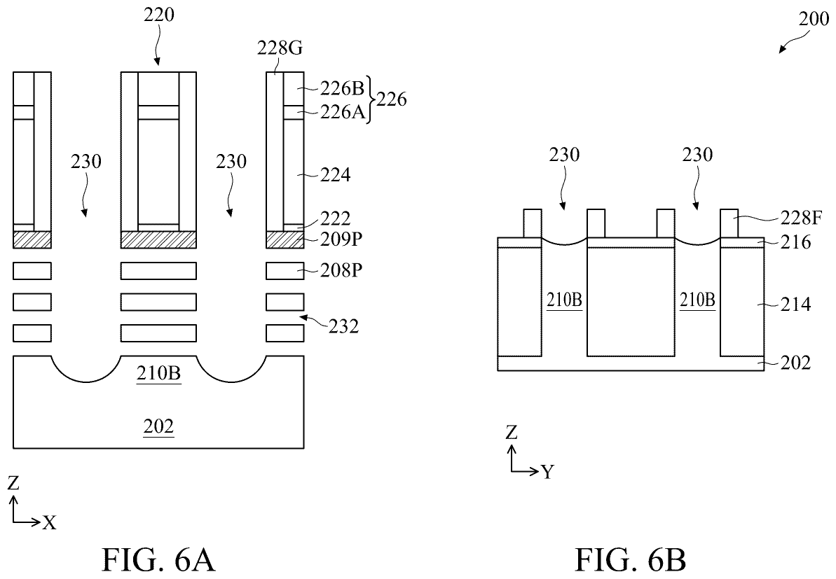

Referring to FIGS. 1 and 6A-6B, the method 100 proceeds to operation 110, where the sacrificial semiconductor portions 206P are removed, in accordance with some embodiments. FIGS. 6A and 6B are cross-sectional views of the GAA device 200 after removing the sacrificial semiconductor portions 206P.

The selective removal of the sacrificial semiconductor portions 206P releases the channel semiconductor portions 208P to form gaps 232 between adjacent channel semiconductor portions 208P and between the bottommost channel semiconductor portions 208P and the base portion 210B in fin structure 210.

In some embodiments, the sacrificial semiconductor portions 206P may be removed by a selective etching process using an etchant that is selective to the material of sacrificial semiconductor portions 206P, such that the sacrificial semiconductor portions 206P are removed without substantially attacking the channel semiconductor portions 208P. In some embodiments, the etching process is an isotropic etching process which can be a dry etching process or a wet etching process. In some embodiments, the selective etching process may include oxidizing the sacrificial semiconductor portions 206P using a suitable oxidizer, such as ozone. Thereafter, the oxidized sacrificial semiconductor portions 206P may be selectively removed. In some embodiments, when the channel semiconductor portions 208P include Si and the sacrificial semiconductor portions 206P include SiGe, the sacrificial semiconductor portions 206P may be selectively removed by applying an HCl gas at a temperature of about 500° C. to about 700° C., or applying a gas mixture of CF₄, SF₆, and CHF₃.

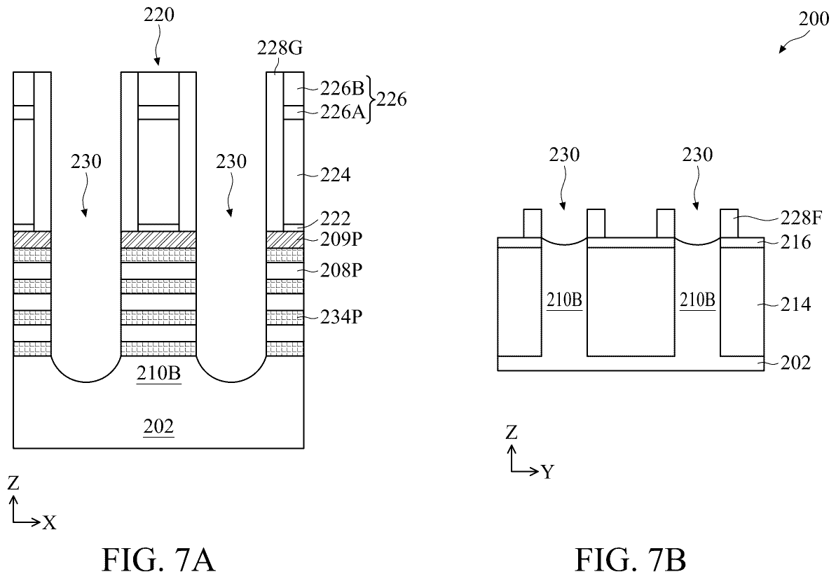

Referring to FIGS. 1 and 7A-7B, the method 100 proceeds to operation 112, where sacrificial dielectric portions 234P are formed to fill the gaps 232, in accordance with some embodiments. FIGS. 7A and 7B are cross-sectional views of the GAA device 200 after forming the sacrificial dielectric portions 234P to fill the gaps 232.

A sacrificial dielectric layer is conformally deposited on the channel semiconductor portions 208P, the base portion 210B, and the sacrificial gate structures 220 to fill the gaps 232 (i.e., the spaces between adjacent channel semiconductor portions 208P). In some embodiments, the sacrificial dielectric layer comprises a dielectric oxide, such as, for example, silicon oxide, silicon dioxide, or a silicon-rich oxynitride. The sacrificial dielectric layer may be formed by a conformal deposition process such as CVD or ALD. In some embodiments, the thickness of the sacrificial dielectric layer is controlled such that the sacrificial dielectric layer pitches off the gaps 232. In some embodiments, the sacrificial dielectric layer fully fills the gaps 232.

Next, an etching process, such as an anisotropic etching process, is performed to remove portions of the sacrificial dielectric layer disposed outside the gaps 232 from the structure. In some embodiments, a wet etch or a diluent hydrofluoric acid (dHF) wash is implemented. The remaining portions of the sacrificial dielectric layer in the gaps 232 form the sacrificial dielectric portions 234P. In some embodiments, the sidewalls of the end portions of the sacrificial dielectric portions 234P are aligned with the sidewalls of the end portions of the channel semiconductor portions 208P.

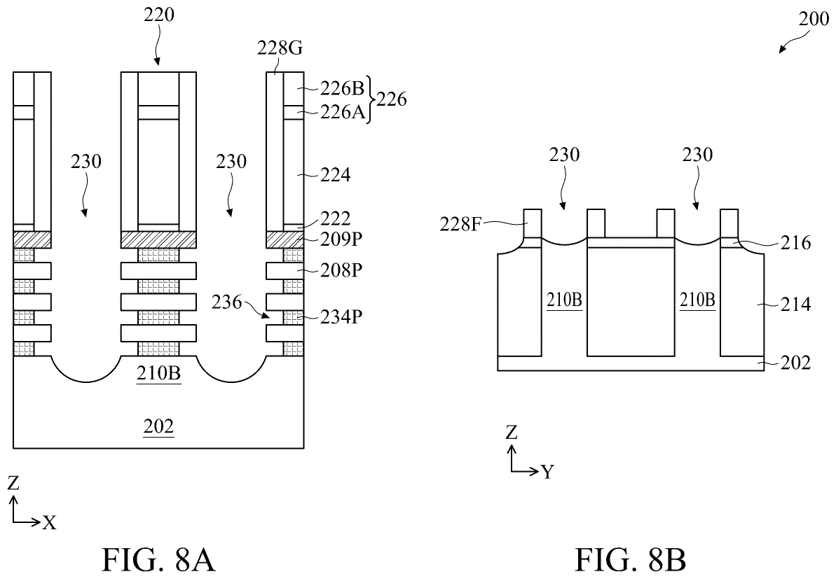

Referring to FIGS. 1 and 8A-8B, the method 100 proceeds to operation 114, where the sacrificial dielectric portions 234P are recessed to form lateral openings 236, in accordance with some embodiments. FIGS. 8A and 8B are cross-sectional views of the GAA device 200 after recessing the sacrificial dielectric portions 234P to form the lateral openings 236.

The end portions of the sacrificial dielectric portions 234P exposed in the source/drain trenches 230 are selectively and laterally recessed to form the lateral openings 236, while the exposed channel semiconductor portions 208P are substantially unetched. In some embodiments, the sacrificial dielectric portions 234P can be selectively etched by using an isotropic dry etching process using an etch gas composition including a halogen-containing compound, ammonia (NH₃), and an amine. In some embodiments, the halogen-containing compound is a fluorine-containing compound. In some embodiments, the fluorine-containing compound may include, but not limited to, hydrogen fluoride (HF), carbon tetrafluoride (CF₄), trifluoromethane (CHF₃), sulfur hexafluoride difluoromethane (CH₂F₂) and hexafluoroethane (C₂F₆). In some embodiments, the amine may include, but not limited to, methylamine, dimethylamine, trimethylamine, ethylamine, diethylamine, triethylamine, methylethylamine, N,N-diethylmethylamine, N,N-dimethylethylamine, isopropylamine, N-ethyldiisopropylamine, and tert-butylamine. In some embodiments, the etch gas composition comprises hydrogen fluoride, ammonia, and trimethyl amine.

In some embodiments, as shown in FIG. 8B, the isotropic etching process also removes at least portions of the etch stop layer 216 not covered by the fin sidewall spacers 228F. In some embodiments, the exposed portions of the etch stop layer 216 are completely removed, exposing the isolation feature 214.

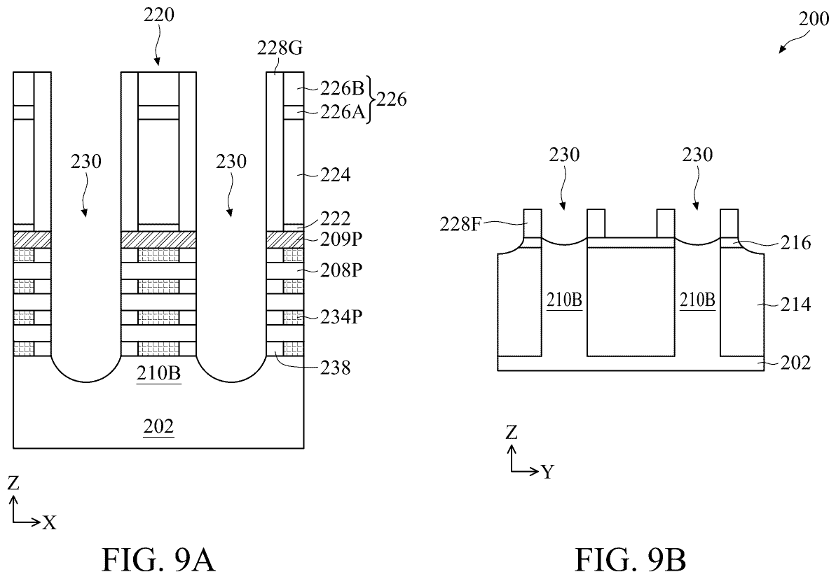

Referring to FIGS. 1 and 9A-9B, the method 100 proceeds to operation 116, wherein inner spacers 238 are formed in the lateral openings 236, in accordance with some embodiments. FIGS. 9A and 9B are cross-sectional views of the GAA device 200 after forming the inner spacers 238.

In some embodiments and as shown in FIG. 9A, the inner spacers 238 generally have the same lateral dimensions as the gate sidewall spacers 228G and contact sidewalls of the sacrificial dielectric portions 234P. To form the inner spacers 238, an inner spacer material layer is deposited over the structure, including in the lateral openings 236. The inner spacer material may include a dielectric nitride, for example, silicon nitride, silicon oxycarbonitride, silicon carbonitride, or any suitable dielectric materials having different etching selectivity from the dielectric oxide constituting the sacrificial dielectric portions 234P. The inner spacer material layer may be formed by CVD, ALD or any other suitable conformal deposition processes. In some embodiments, the inner spacer material layer may be formed to have a thickness such that the lateral openings 236 are filled by the inner spacer material layer.

An etching process, such as an anisotropic etching process, is then performed to remove portions of the inner spacer material layer disposed outside the lateral openings 236. The remaining portions of the inner spacer material layer (i.e., portions disposed inside the inner spacer recesses) form the inner spacers 238. In some embodiments, the anisotropic etching process may be a wet etching process that includes use of an etchant such as, for example, buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. In some embodiments, the anisotropic etching process may be a dry etching process that includes use of an oxygen-containing gas, hydrogen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

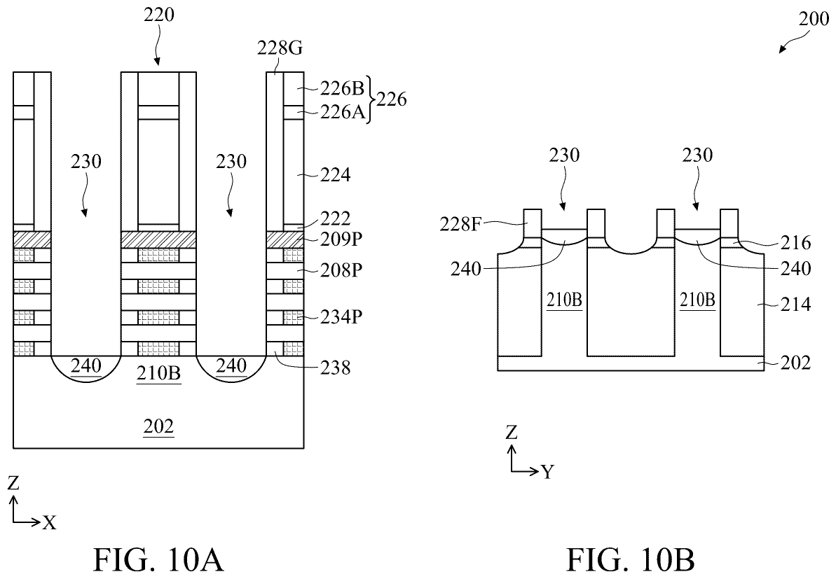

Referring to FIGS. 1 and 10A-10B, the method 100 proceeds to operation 118, where epitaxial semiconductor regions 240 are formed at the bottom of the source/drain trenches 230, in accordance with some embodiments. FIGS. 10A and 10B are cross-sectional views of the GAA device 200 after forming the epitaxial semiconductor regions 240.

The epitaxial semiconductor regions 240 are formed at bottoms of the source/drain trenches 230. In some embodiments, the epitaxial semiconductor regions 240 have top surfaces substantially level with the top surfaces of the base portions 210B. In some embodiments, the epitaxial semiconductor regions 240 are formed by epitaxial growth of a material having similar composition as the base portions 210B. In some embodiments, the epitaxial semiconductor regions 240 include undoped silicon, silicon carbide, silicon phosphide, silicon germanium or other suitable material, which may be epitaxially grown by, for example, MBE, MOCVD, or VPE.

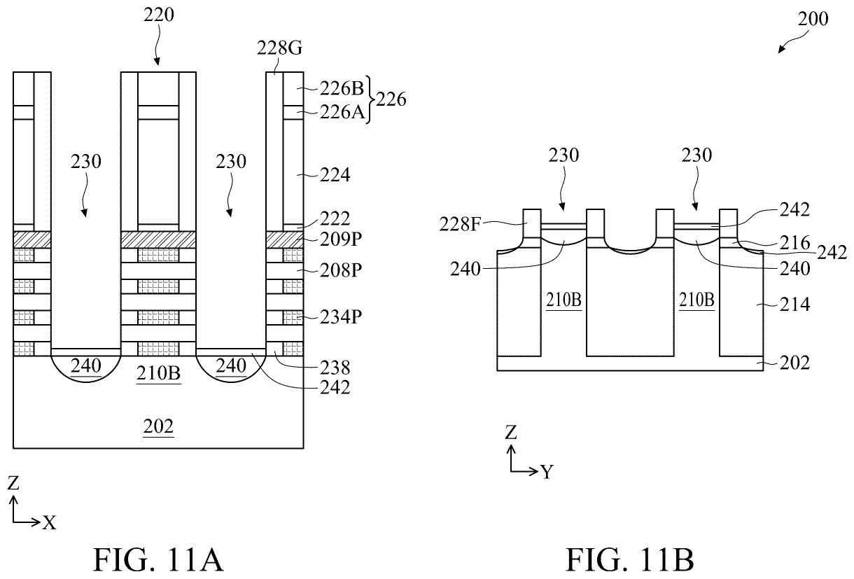

Referring to FIGS. 1 and 11A-11B, the method 100 proceeds to operation 120, where bottom dielectric features 242 are formed on the epitaxial semiconductor regions 240 and isolation feature 214, in accordance with some embodiments. FIGS. 11A and 11B are cross-sectional views of the GAA device 200 after forming the bottom dielectric features 242.

The bottom dielectric features 242 are formed on top surfaces of the epitaxial semiconductor regions 240 and portions of the isolation feature 214 not covered by the fin sidewall spacers 228F. In some embodiments, the bottom dielectric features 242 may be formed of a dielectric material that is not amenable for epitaxial growth such that it may be used to restrict epitaxial growth of semiconductor materials from the epitaxial semiconductor regions 240. In some embodiments, the bottom dielectric features 242 may include silicon nitride, aluminum oxynitride, hafnium oxide, lanthanum oxide, aluminum oxide, zirconium nitride, silicon carbide, zinc oxide, silicon oxycarbonitride, silicon, yttrium oxide, tantalum carbonitride, silicon carbonitride, zirconium aluminum oxide, titanium oxide, tantalum oxide, or zirconium oxide, silicon oxycarbide, and silicon oxide. In some embodiments, the bottom dielectric features 242 may include silicon nitride. In some embodiments, the bottom dielectric features 242 may be formed by first blanketly depositing a dielectric material layer to fill the source/drain trenches 230. In some embodiments, the dielectric material layer may be deposited using, for example, CVD, PECVD, or PVD. Subsequently, the dielectric material layer is recessed until a top surface of the dielectric material layer is below the bottom surface of the bottommost channel semiconductor portions 208P. As shown in FIGS. 11A and 11B, upon completion of the recess etching process, the sidewalls of the channel semiconductor portions 208P are exposed, while the epitaxial semiconductor regions 240 remain covered by the remaining portions of the dielectric material layer, which constitute the bottom dielectric features 242. Alternatively, the bottom dielectric features 242 are formed by oxidizing or nitridizing surface portions of the epitaxial semiconductor regions 240. In such case, the bottom dielectric feature 242 is only formed over the epitaxial semiconductor regions 240, but not the exposed portions of the isolation feature 214 which are not covered by the fin sidewall spacers 228F.

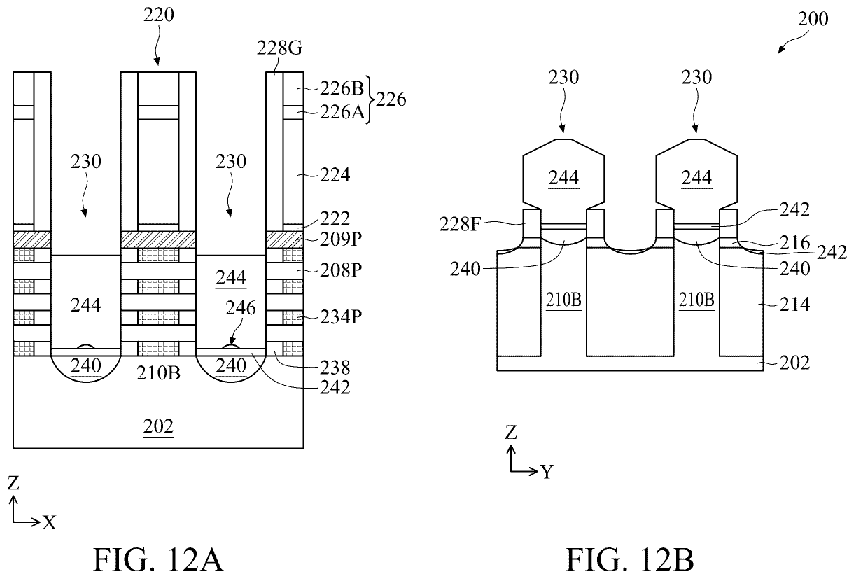

Referring to FIGS. 1 and 12A-12B, the method 100 proceeds to operation 122, where source/drain features 244 are formed in the source/drain trenches 230, in accordance with some embodiments. FIGS. 12A and 12B are cross-sectional views of the GAA device 200 after forming the source/drain features 244. The source/drain features 244 are disposed on opposite sides of the sacrificial dielectric portions 234P and the channel semiconductor portions 208P such that the source/drain features 244 are in contact with the channel semiconductor portions 208P and the inner spacers 238.

In embodiments of the present disclosure, the source/drain features 244 are epitaxially grown in the source/drain trenches 230. The epitaxy process may include CVD deposition (for example, vapor-phase epitaxy (VPE) ultra-high vacuum CVD (UHV-CVD), low pressure CVD (LPCVD), plasma-enhanced CVD (PECVD)), molecular beam epitaxy (MBE), other suitable selective epitaxy growth processes, or combinations thereof. Because the epitaxial semiconductor regions 240 are covered by the bottom dielectric features 242, no nucleation sites are present at the bottom of the source/drain trenches 230 during the selective source/drain epitaxy growth. As a result, the semiconductor material forming the source/drain features 244 grows laterally from the exposed sidewalls of the channel semiconductor portions 208P, which have a (110) crystal orientation, located on opposite sides of the source/drain trenches 230.

In embodiments of the present disclosure, the selective epitaxy growth proceeds in a conformal and continuous manner. The source/drain semiconductor material is epitaxially grown layer-by-layer from the (110)-oriented sidewall surfaces of the opposing channel semiconductor portions 208P. This lateral epitaxial growth progresses along the widthwise direction of the source/drain trenches 230 until the final pair of layers meet and join within the source/drain trenches 230. The resulting conformal epitaxial semiconductor source/drain layers each exhibit a (110) side surface crystal orientation.

In some embodiments, the source/drain feature 244 has a greater width than the width of the epitaxial semiconductor region 240 and the underlying base portion 210B. As a result, a portion of the source/drain feature 244 overhangs the isolation feature 214. In some embodiments, because epitaxy growth does not occur on the bottom dielectric feature 242, a void 246 may form at the bottom of each source/drain trench 230 between the source/drain feature 244 and the bottom dielectric feature 242.

The source/drain features 244 may include any suitable material for n-type or p-type FET devices. For example, when n-type FET devices are formed, the source/drain features 244 may include materials exerting a tensile strain in the channel regions, such as Si, SiC, SiCP, SiP, or the like, and may be in-situ doped during the epitaxy process by introducing an n-type dopant, such as phosphorus (P), arsenic (As), or ex-situ doped using an implantation process (i.e., a junction implant process). Likewise, when p-type FET devices are formed, the source/drain features 244 may include materials exerting a compressive strain in the channel regions, such as Si, SiGe, SiGeB, Ge, GeSn, or the like and may be in-situ doped during the epitaxy process by introducing a p-type dopant, such as boron (B), aluminum (Al), gallium (Ga), and indium (In), or ex-situ doped using an implantation process (i.e., a junction implant process). In some embodiments, the source/drain features 244 are p-type source/drain features and include boron-doped SiGe. In some embodiments, the source/drain features 244 are n-type source/drain features and include phosphorus-doped Si.

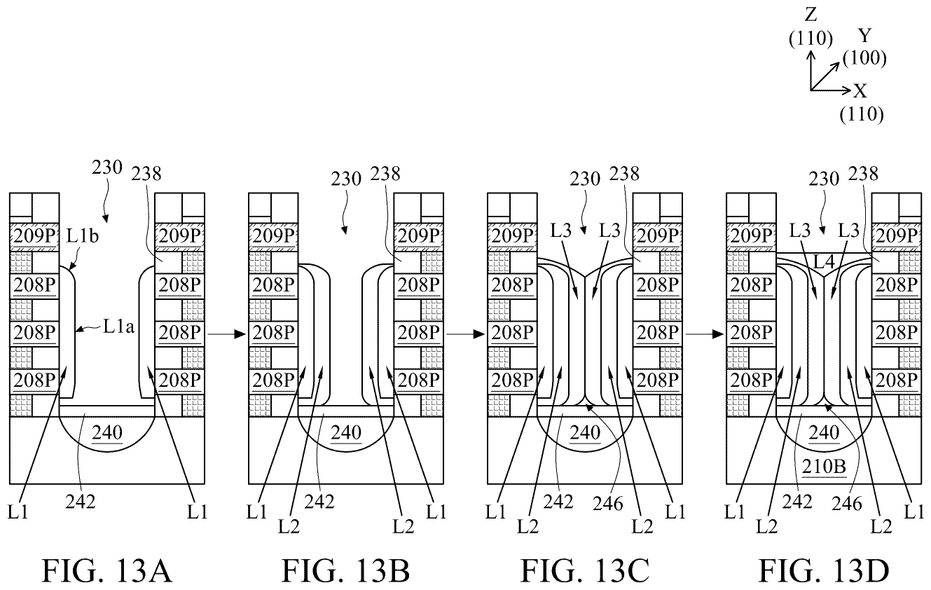

FIGS. 13A-13D are cross-sectional views illustrating the formation of a source/drain feature 244 through a layer-by-layer selective epitaxy grown process, in accordance with some embodiments of the present disclosure.

As shown in FIG. 13A, the formation of a source/drain feature 244 is initiated by the epitaxial growth of first source/drain epitaxial layer L1 on opposite sidewalls of the source/drain trench 230, using the sidewalls of the channel semiconductor portions 208P as seed layers. During the layer-by-layer selective epitaxy growth process, the first source/drain epitaxial layers L1 are selectively grown from the sidewalls of the channel semiconductor portions 208P but not from the dielectric surfaces, including hard mask portions 209P, the inner spacers 238, and the bottom dielectric features 242 exposed within the source/drain trench 230. In embodiments of the present disclosure, since the fin structure 210 is epitaxially grown from a substrate 202 with a (110) surface crystal orientation, the sidewalls, as well as the top and bottom surfaces of the channel semiconductor portions 208P, also exhibit a (110) crystal orientation. As a result, epitaxial growth occurs primarily in the <110> direction, enabling the formation of conformal source/drain epitaxial layers L1 that contact sidewalls of the channel semiconductor portions 208P and sidewalls of the inner spacers 238. The bottom dielectric features 242 remain exposed within the source/drain trenches 230 after the first source/drain epitaxial layers L1 are formed. Each of the first source/drain epitaxial layers L1 is formed with a side surface (L1a) as well as top and bottom surfaces (L1b), all maintaining a (110) crystal orientation. In some embodiments, the first source/drain epitaxial layers L1 is formed to have a thickness ranging from about 2 nm to about 6 nm. Because the channel semiconductor portions 208P have the same (110) surface crystal orientation along both the X and Z directions, the inner spacers 238 have a minimal impact on the thickness variations of the first source/drain epitaxial layers, with deviations below 1 nm.

As shown in FIG. 13B, as the layer-by-layer selective epitaxy growth process continues, conformal second source/drain epitaxial layers L2 are formed on the respective first source/drain epitaxial layers L1. The second source/drain epitaxial layers L2 are grown epitaxially from all facets of the first source/drain epitaxial layers L1, including side, top, and bottom surfaces. The thickness of the second source/drain epitaxial layers L2 is controlled to prevent the formation of grain boundaries. In some embodiments, the material and/or method of forming the second source/drain epitaxial layers L2 can be the same as or similar to those of the first source/drain epitaxial layers L1. In other embodiments, the second source/drain epitaxial layers L2 may have a composition different from the composition of the first source/drain epitaxial layers L1. For example, in some embodiments, the first source/drain epitaxial layers L1 and the second source/drain epitaxial layers L2 may be composed of different semiconductor materials and/or different dopant concentrations. In other embodiments, the second source/drain epitaxial layers L2 may be composed of the same semiconductor material as the first source/drain epitaxial layers L1, but with a different dopant concentration. For instance, the second source/drain epitaxial layers L2 may have a higher dopant concentration than the first source/drain epitaxial layers L1.

As shown in FIG. 13C, the layer-by-layer selective epitaxy growth process continues to form conformal third source/drain epitaxial layers L3 on the respective second source/drain epitaxial layers L2. The third source/drain epitaxial layers L3 are grown epitaxially from all facets of the second source/drain epitaxial layers L2, including side, top, and bottom surfaces. The thickness of the third source/drain epitaxial layers L3 is controlled to prevent the formation of grain boundaries. In some embodiments, the material and/or method of forming the third source/drain epitaxial layers L3 can be the same as or similar to those of the second source/drain epitaxial layers L2. In other embodiments, the third source/drain epitaxial layers L3 may have a composition different from the composition of the second source/drain epitaxial layers L2. For example, in some embodiments, the second source/drain epitaxial layers L2 and the third source/drain epitaxial layers L3 may be composed of different semiconductor materials and/or different dopant concentrations. In other embodiments, the third source/drain epitaxial layers L3 may be composed of the same semiconductor material as the second source/drain epitaxial layers L2, but with a different dopant concentration. For instance, the third source/drain epitaxial layers L3 may have a higher dopant concentration than the second source/drain epitaxial layers L2.

In embodiment as shown in FIG. 13C, the third source/drain epitaxial layers L3 are joined or connected at or proximal to the center of the source/drain trench 230, merging the neighboring channel semiconductor portions 208P. Because no semiconductor material can be epitaxially grown from the bottom dielectric feature 242 at the bottom of the source/drain trench 230, a void 246 is formed between the lower end facets of the third source/drain epitaxial layers L3 and the bottom dielectric feature 242. While the illustrated embodiment depicts three epitaxial layers (L1-L3) bridging the neighboring channel semiconductor portions 208P, the conformal selective epitaxial growth process can be repeated as needed until the final pair of source/drain epitaxial layers fully merge, completing the bridge. For instance, the source/drain formation may be achieved with only two epitaxial deposition processes if the second source/drain epitaxial layers (L2) are sufficient to merge the first source/drain epitaxial layers (L1), in which case the formation of the third source/drain epitaxial layers (L3) would be omitted.

As shown in FIG. 13D, a fourth source/drain epitaxial layer L4 is formed on the third source/drain epitaxial layers L3. The fourth source/drain epitaxial layer L4 is grown epitaxially from the upper end facets of the third source/drain epitaxial layers L3. The epitaxy growth continues until the fourth source/drain epitaxial layer LA is formed with a planar top surface. In some embodiments and as shown in FIG. 13D, the top surface of the fourth source/drain epitaxial layer L4 is located between the top surface of the topmost channel semiconductor portion 208P and the bottom surface of the hard mask portion 209P. In some embodiments, the top surface of the fourth source/drain epitaxial layer LA is coplanar with the bottom surface of the hard mask portion 209P (not shown).

The first source/drain epitaxial layers L1, the second source/drain epitaxial layers L2, the third source/drain epitaxial layers L3, and the fourth source/drain epitaxial layer L4 can be collectively referred to as a source/drain feature 244.

In embodiments of the present disclosure, the continuous selective epitaxy growth of conformal source/drain epitaxial layers from the (110)-oriented sidewall surfaces prevents early sheet end merging, enabling the formation of void-free source/drain features 244. Eliminating voids in the source/drain features 244 ensures low resistivity between the source/drain features 244 and the channels, even for channels with wider widths. As a result, the device performance is enhanced.

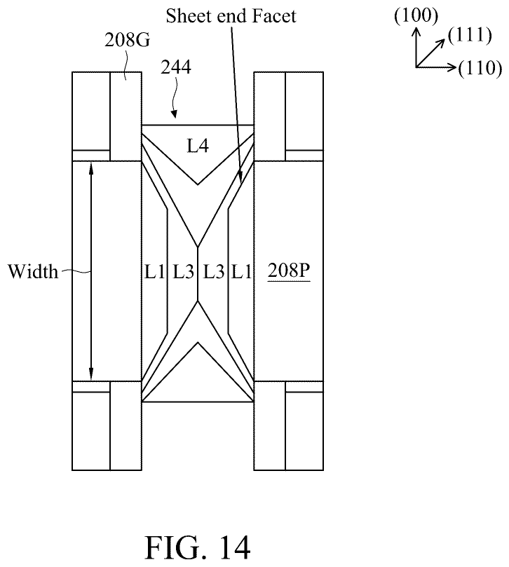

FIG. 14 is a plan view of the source/drain feature 244 along the X-Y plane. As illustrated in FIG. 14, the selective epitaxial growth occurs from the sidewalls of the channel semiconductor portions 208P, which have a (100) crystal orientation. This growth proceeds in a conformal, layer-by-layer, continuous manner, resulting in the formation of (110) type side facet and (111) type end facets in each conformal source/drain epitaxial layer, such as the first (L1), second (L2), and third (L3) conformal source/drain epitaxial layer.

In some embodiments, a thermal annealing process is performed following the epitaxial growth of the source/drain features or ex-situ doping of the source/drain features 244. This process causes dopants to be injected into portions of the channel semiconductor portions 208P that are in contact with the source/drain features 244. This annealing process effectively extends the source/drain features 244 into the end portions of the channel semiconductor portions 208P, reducing the parasitic resistance of the nanosheet FET devices. In other embodiments, the thermal annealing process is performed in a later process (such as after the formation of the high-k gate dielectric layers) so that the same annealing process can serve two purposes at the same time: driving dopants into the channel semiconductor portions 208P, and improving the reliability of the high-k gate dielectric. After annealing, sidewalls of the source/drain features 244 may be aligned with the inner sidewalls of the gate sidewall spacers 228G (not shown). In some other embodiments, the thermal annealing process is omitted, and the sidewall of the source/drain features 244 are aligned with the outer sidewalls of the gate sidewall spacers 228G, as shown in FIG. 12A.

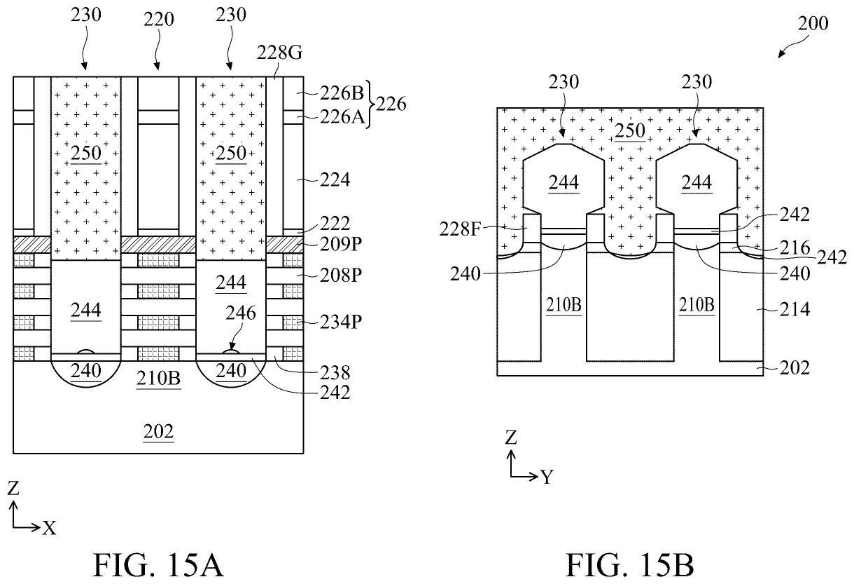

Referring to FIGS. 1 and 15A-15B, the method 100 proceeds to operation 124, where an interlayer dielectric (ILD) layer 250 is formed over the source/drain features 244 and the bottom dielectric features 242, in accordance with some embodiments. FIGS. 15A and 15B are cross-sectional views of the GAA device 200 after forming the ILD layer 250.

In some embodiments, the ILD layer 250 may include a low-k dielectric material having a dielectric constant lower than the dielectric constant (about 3.9) of silicon dioxide. The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOₓC_{y}), spin-on-glass (SOG), or combinations thereof. The ILD layer 250 may include a multi-layer structure having multiple dielectric materials and may be formed by CVD, flowable CVD (FCVD), spin coating, or other suitable deposition processes. In some embodiments, forming the ILD layer 250 further includes performing a CMP process to planarize a top surface of the ILD layer 250, such that the masks 226 are exposed. The top surface of the ILD layer 250 may be coplanar with the topmost surfaces of the masks 226 (e.g., the top surfaces of the second masks 226B) and the top surfaces of the gate sidewall spacers 228G.

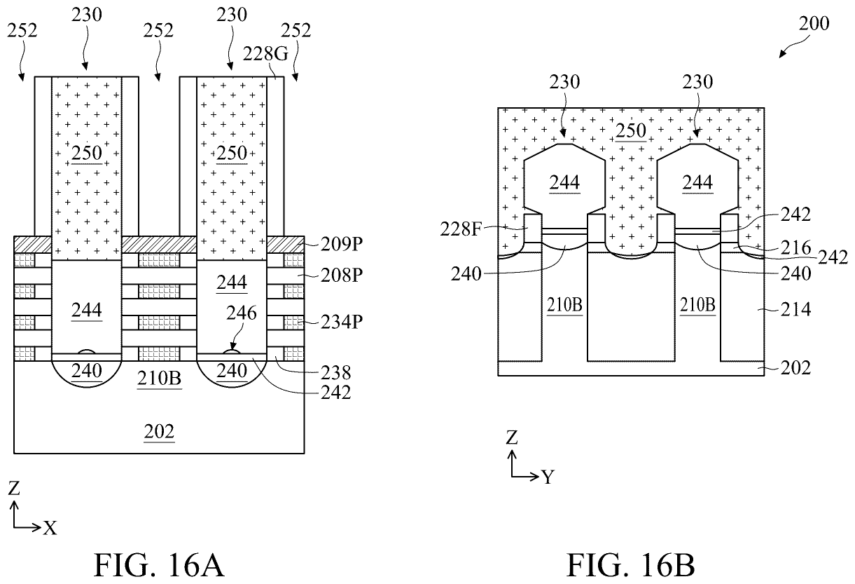

Referring to FIGS. 1 and 16A-16B, the method 100 proceeds to operation 126, where the sacrificial gate structures 220 are removed, in accordance with some embodiments. FIGS. 16A and 16B are cross-sectional views of the GAA device 200 after removing the sacrificial gate structures 220.

One or more etching processes are performed to selectively remove various components of each of the sacrificial gate structures 220, including the sacrificial gate dielectric 222, the sacrificial gate electrode 224, and the first and second masks, 226A and 226B. The removal of sacrificial gate structure 220 forms a gate trench 252 that exposes hard mask portion 209P, channel semiconductor portions 208P, and sacrificial semiconductor portions 206P in the channel region of each fin structure 210. The ILD layer 250 protects the source/drain features 244 during the etching process. The etching process may be a dry etching process, a wet etching process, or a combination thereof. The etching process can be tuned such that the sacrificial gate dielectric 222, the sacrificial gate electrode 224, the first and second masks 226A and 226B are removed without (or minimally) etching other elements in the GAA device 200, including the ILD layer 250, the source/drain features 244, the gate sidewall spacers 228G, and the hard mask portion 209P. For example, in instances where the sacrificial gate electrode 224 is composed of polysilicon and the ILD layer 250 is composed of silicon oxide, a wet etchant such as a TMAH solution may be used to selectively remove the sacrificial gate electrode 224. The sacrificial gate dielectric 222 is thereafter removed using plasma dry etching and/or wet etching.

Referring to FIGS. 1 and 17A-17B, the method 100 proceeds to operation 128, where the sacrificial dielectric portions 234P are removed, in accordance with some embodiments. FIGS. 17A and 17B are cross-sectional views of the GAA device 200 after removing the sacrificial dielectric portions 234P.

The selective removal of the sacrificial dielectric portions 234P releases the channel semiconductor portions 208P to form channel nanostructures 208C. In some embodiments, the channel nanostructures 208C are nanosheets. In some embodiments, the sacrificial dielectric portions 234P may be removed by a selective etching process using an etchant that is selective to the material of sacrificial dielectric portions 234P, such that the sacrificial dielectric portions 234P are removed without substantially attacking the channel semiconductor portions 208P, the gate sidewall spacers 228G, the inner spacers 238, and the ILD layer 250. In some embodiments, the etching process is an isotropic etching process which can be a dry etching process or a wet etching process. The inner spacers 238 serve as etch stop layers to protect the source/drain features 244 during removal of the sacrificial dielectric portions 234P.

In some embodiments, after exposing the channel nanostructures 208C by removing the sacrificial dielectric portions 234P, a trimming operation may be performed to reduce the thickness of the channel nanostructures 208C, thereby improving the gate fill window. The trimming operation can utilize any suitable etching process, such as dry etching, wet etching, or a combination of both. The resulting channel nanostructures 208C may have a thickness ranging from 3 nm to 8 nm.

As shown in FIG. 17A, gaps 254 (e.g., empties spaces) are formed between adjacent channel nanostructures 208C, between the topmost channel nanostructure 208C and the hard mask portion 209P, and between the bottommost channel nanostructure 208C and the base portion 210B, as a result of the removal of the sacrificial dielectric portions 234P and nanosheet trimming. The gaps 254 define the spacing between adjacent channel nanostructures 208C. In some embodiments, the spacing between the adjacent channel nanostructures 208C (also referred to as sheet-to-sheet spacing) may range from about 8 nm to about 15 nm.

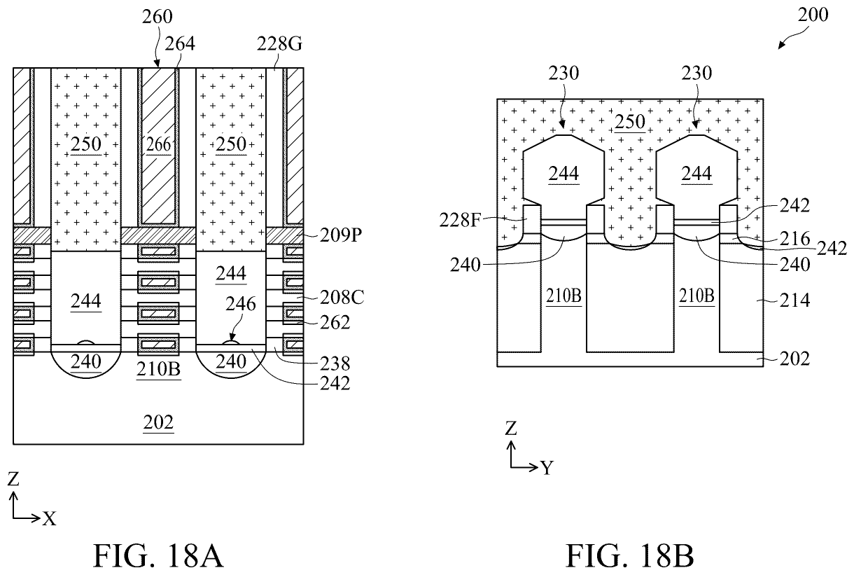

Referring to FIGS. 1 and 18A-18B, the method 100 proceeds to operation 130, where replacement gate structures 260 are formed in the gate trenches 252 and the gaps 254, in accordance with some embodiments. FIGS. 18A and 18B are cross-sectional views of the GAA device 200 after forming the replacement gate structure 260. Each replacement gate structure 260 is deposed over and between the vertically spaced channel nanostructures 208C, respectively and over the base portion 210B. In some embodiments, the replacement gate structure 260 includes an interfacial layer 262, a gate dielectric layer 264, and a gate electrode layer 266. In some embodiments, the replacement gate structure 260 may include a conformal gate work function layer between the gate dielectric layer 264 and the gate electrode layer 266.

The interfacial layer 262 is formed on the exposed surfaces of the channel nanostructures 208C and the base portion 210B. The interfacial layer 262 promotes adhesion of the gate dielectric layer 264 to the channel nanostructures 208C. In some embodiments, the interfacial layer 262 may include a dielectric material such as silicon oxide. In some embodiments, the interfacial layer 262 may be formed by chemical oxidation or thermal oxidation of surface portions of the channel nanostructures 208C and the base portion 210B. For example, in some embodiments, the interfacial layer 262 is formed using an ozonated deionized water comprising ozone. The thickness of the interfacial layer 262 ranges from about 0.5 nm to about 1.5 nm. In some embodiments, the interfacial layer 262 is about 1 nm thick, achieved by oxidizing around 1 nm of the channel nanostructures 208C.

Afterwards, the gate dielectric layer 264 is conformally deposited over the interfacial layer 262 and the hard mask portion 209P. The gate dielectric layer 264 wraps around the channel nanostructures 208C and the hard mask portion 209P, and is on the sidewalls of the gate trench 252. In some embodiments, the gate dielectric layer 264 may include a high-k dielectric material having a dielectric constant greater than silicon dioxide. Examples of high-k dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), titanium oxide (TiO₂), and hafnium oxide-alumina (HfO₂—Al₂O₃) alloy. The gate dielectric layer 264 may be formed by CVD, ALD or other suitable conformal deposition methods. In some embodiments, the gate dielectric layer 264 is formed using a conformal deposition process such as ALD in order to ensure that the high-k gate dielectric layer 264 has a uniform thickness around each of channel nanostructures 208C. The gate dielectric layer 264 may be formed to have a thickness ranging from about 1 nm to about 2.5 nm. In some embodiments, the gate dielectric layer 264 may be formed to have a thickness of about 1.5 nm.

If present, a work function layer (not shown) may be subsequently deposited over the gate dielectric layer 264. For an n-type FET, the work function layer may include an n-type work function layer adapted to tune the threshold voltage for n-type FET. Suitable n-type work function materials include, but are not limited to, aluminum (Al), titanium aluminum (TiAl), titanium aluminum carbide (TiAlC), tantalum aluminum carbide (TaAlC), tantalum aluminum silicide (TaSiAl), tantalum silicon carbide (TaSiC), tantalum silicide (TaSi), hafnium carbide (HfC), and combinations thereof. For a p-type FET, the work function layer may include a p-type work function layer adapted to tune the threshold voltage for p-type FET. In some embodiments, the p-type work function layer includes tungsten (W), molybdenum (Mo), tungsten nitride (WN), tungsten carbon nitride (WCN), tantalum silicon nitride (TaSiN), or tantalum nitride (TaN). The work function layer may be formed by a conformal deposition process such as, for example, ALD or CVD. In some embodiments, the work function layer may be formed to have a thickness ranging from about 1.5 nm to about 2.5 nm.

Next, the gate electrode layer 266 is formed on the work function layer, if present, or on the gate dielectric layer 264 to fill any remaining volumes in the gate trench 252 and the gaps 254. The gate electrode layer 266 may include a conductive material such as tungsten, cobalt, ruthenium, iridium, molybdenum, copper, aluminum, or combinations thereof. The gate electrode layer 266 may be formed by any suitable deposition process such as CVD, PECVD, PVD, or electrochemical plating.

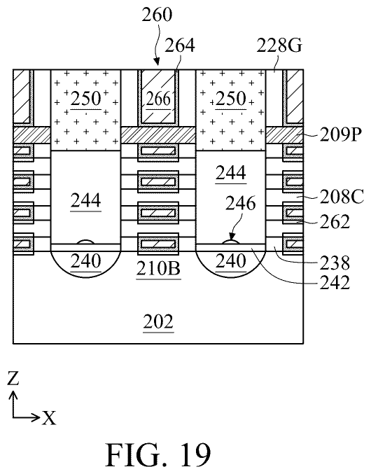

Next, excess portions of the gate dielectric layer 264, the work function layer, if present, and the gate electrode layer 266 that are deposited on the top surface of the ILD layer 250 and the gate sidewall spacers 228G are removed in a planarization process such as a CMP process to form the replacement gate structure 260. The top surface of the replacement gate structure 260 may be coplanar with the top surfaces of the ILD layer 250 and the gate sidewall spacers 228G. In some embodiments and as shown in FIG. 19, some portions of the gate sidewall spacers 228G and ILD layer 250 are also removed in the CMP process to reduce the thickness of the gate electrode layer 266 over the hard mask portion 209P, thereby helping to reduce RC delay.

The replacement gate structure 260 thus formed surrounds the channel nanostructures 208C and fills the gaps 254 between the channel nanostructures 208C, the gap 254 between the hard mask portion 209P and the topmost channel nanostructure 208C, and the gap 254 between the bottommost channel nanostructure 208C and the mesa structure base portion 210B. Between the channel nanostructures 208C, the gate electrode layer 266 is circumferentially surrounded (in the cross-sectional view) by the gate dielectric layer 264. In the portion of the replacement gate structure 260 formed over the hard mask portion 209P, the gate electrode layer 266 is formed over the gate dielectric layer 264 with the gate dielectric layer 264 wrapping around the gate electrode layer 266.

Additional processing may be performed to finish the fabrication of the GAA device 200. For example, gate contact (not illustrated for simplicity) and the source/drain contacts may be formed to electrically couple to the replacement gate structure 260 and the source/drain features 244, respectively. An interconnect structure may then be formed over the source/drain contacts and the gate contact. The interconnect structure may include a plurality of dielectric layers surrounding metallic features, including conductive traces and conductive vias, which form electrical connection between devices on the substrate 202, such as the GAA device 200.

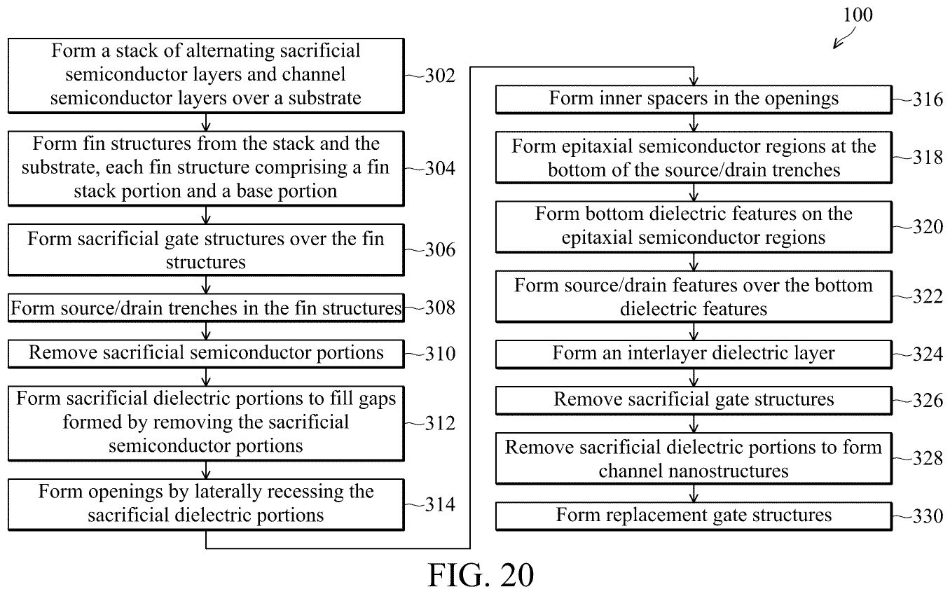

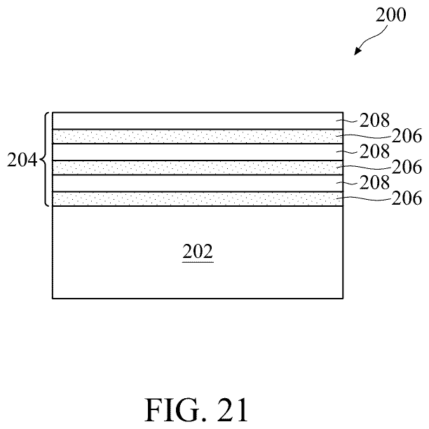

FIG. 20 is a flowchart of a method 300 of forming a GAA device 400, in accordance with some embodiments of the present disclosure. FIGS. 21-35B are various views of the GAA device 400 at various stages of the method 300, in accordance with some embodiments. Some embodiments of method 300 are described below in conjunction with FIGS. 21-35B with reference to the GAA device 400. The same components in the GAA device 400 are noted by the same reference numerals as those used in the GAA device 200. The method 300 is merely an example and is not intended to limit the present disclosure beyond what is explicitly recited in the claims. Additional operations can be provided before, during, and after the method 300, and some operations described can be replaced, eliminated, or moved around for additional embodiments of the method.

Referring to FIGS. 20 and 21, at operation 302, the method 300 forms an initial structure of the GAA device 400. FIG. 21 is a cross-sectional view of the initial structure of the GAA device 400, in accordance with some embodiments. This initial structure includes a substrate 202 and a stack 204 over the substrate 202. The stack 204 includes alternating sacrificial semiconductor layers 206 and channel semiconductor layers 208 with the channel semiconductor layer 208 being the topmost layer. The processes described above with respect to FIG. 2 are performed to form the stack 204 of the alternating sacrificial and channel semiconductor layers 206 and 208 over the substrate 202.

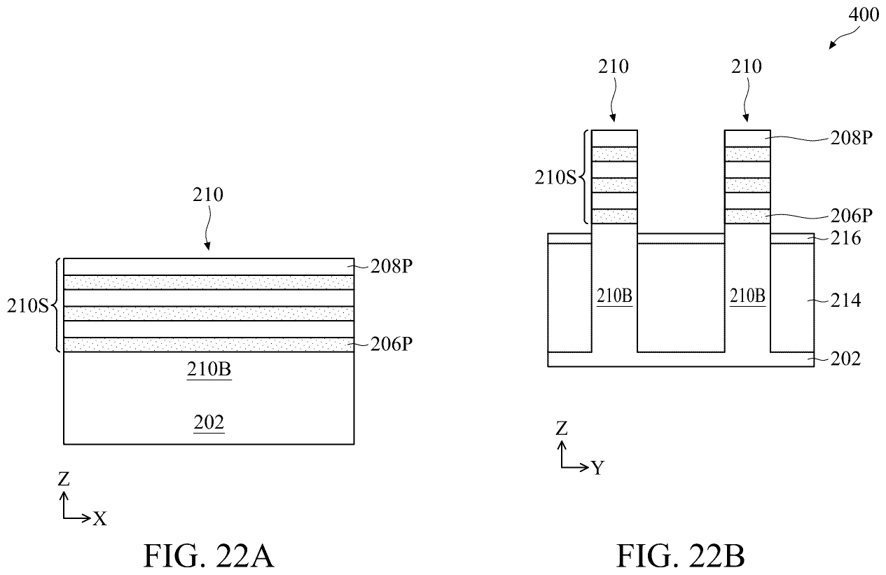

Referring to FIGS. 20 and 22A-22B, the method 300 proceeds to operation 304, where fin structures 210 are formed from the stack 204 by lithography and etching, in accordance with some embodiments. FIGS. 22A and 22B are cross-sectional views of the GAA device 400 after forming the fins structures 210. Each fin structure 210 includes a base portion 210B formed from the substrate 202 and a fin stack portion 210S formed from the stack 204. The fin stack portion 210S includes alternating sacrificial semiconductor portions 206P and channel semiconductor portions 208P, with the channel semiconductor portion 208P being the topmost semiconductor portion. The base portion 210B is surrounded by an isolation feature 214 and an etch stop layer 216. The processes described above with respect to FIGS. 3A and 3B are performed to form the fin structure 210, the isolation feature 214, and the etch stop layer 216.

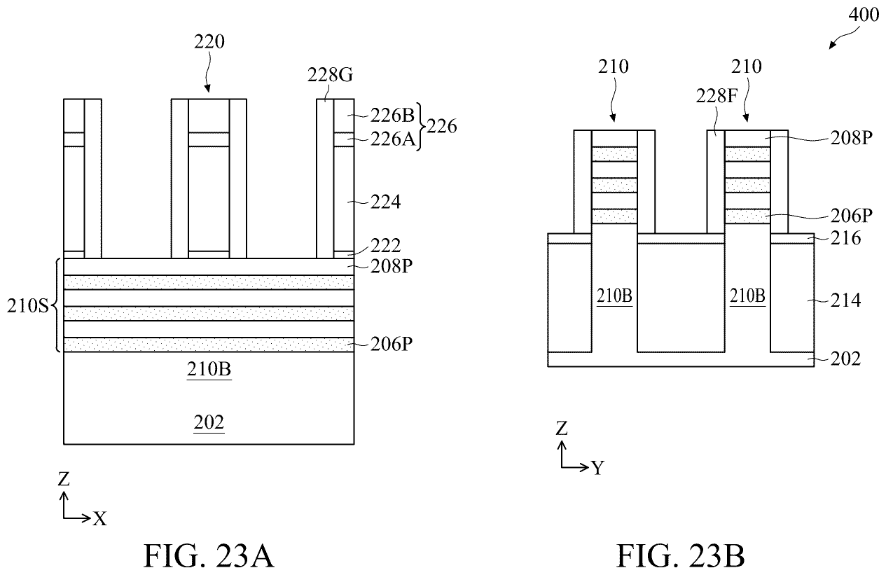

Referring to FIGS. 20 and 23A-23B, the method 300 proceeds to operation 306, where sacrificial gate structures 220 are formed over the fin structures 210 and the etch stop layer 216, followed by forming gate sidewalls spacers 228G and fin sidewall spacers 228F, in accordance with some embodiments. FIGS. 23A and 23B are cross-sectional views of the GAA device 400 after forming the sacrificial gate structures 220, the gate sidewall spacers 228G, and the fin sidewall spacers 228F. Each sacrificial gate structure 220 is formed across each fin structure 210, along the sidewalls of the fin stack portion 210S of each fin structure 210 and over the top surface of each topmost channel semiconductor portion 208P. The sacrificial gate structure 220 serves as a placeholder and will be replaced with a metal gate structure. The processes described above with respect to 4A and 4B are performed to form the sacrificial gate structures 220, the gate sidewall spacers 228G, and the fin sidewall spacers 228F.

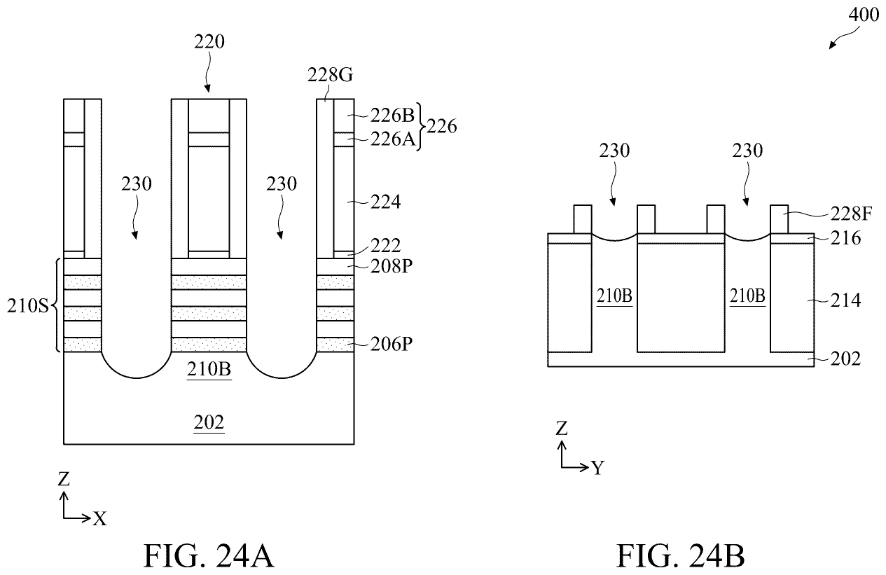

Referring to FIGS. 20 and 24A-24B, the method 300 proceeds to operation 308, where source/drain trenches 230 are formed in the fin structures 210, in accordance with some embodiments. FIGS. 24A and 24B are cross-sectional views of the GAA device 400 after forming the source/drain trenches 230. The processes described above with respect to FIGS. 5A and 5B are performed to form the source/drain trenches 230.

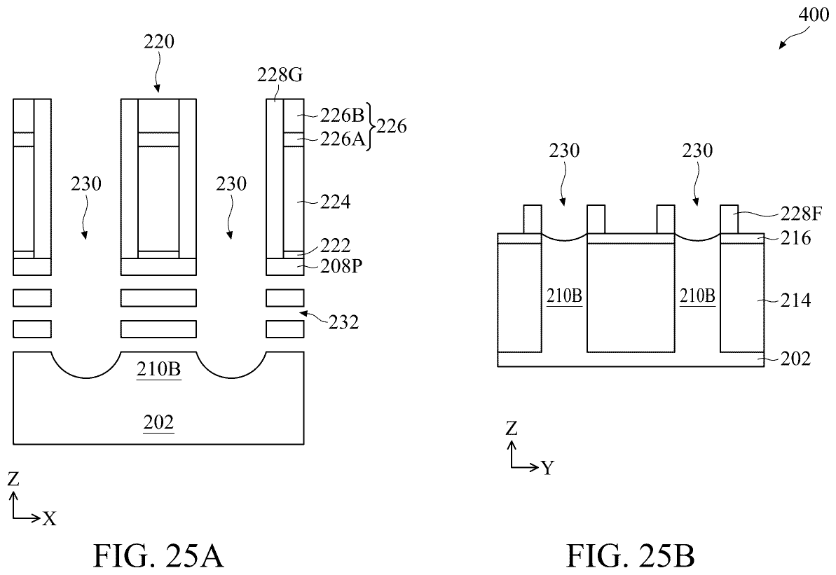

Referring to FIGS. 20 and 25A-25B, the method 300 proceeds to operation 310, where the sacrificial semiconductor portions 206P are removed, in accordance with some embodiments. FIGS. 25A and 25B are cross-sectional views of the GAA device 400 after removing the sacrificial semiconductor portions 206P. The selective removal of the sacrificial semiconductor portions 206P releases the channel semiconductor portions 208P to form gaps 232 between adjacent channel semiconductor portions 208P and between the bottommost channel semiconductor portions 208P and the base portion 210B in fin structure 210. The processes described above with respect to FIGS. 6A and 6B are performed to remove the sacrificial semiconductor portions 206P.

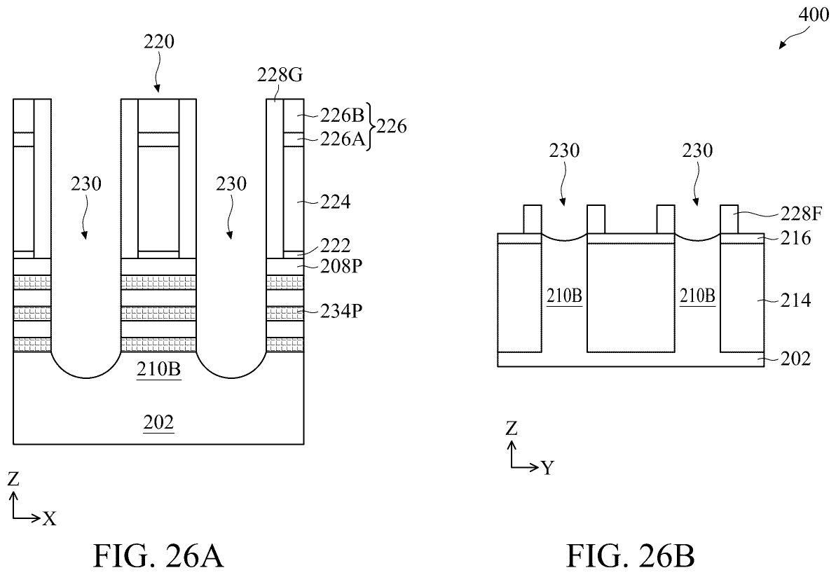

Referring to FIGS. 20 and 26A-26B, the method 300 proceeds to operation 312, wherein sacrificial dielectric portions 234P are formed to fill the gaps 232, in accordance with some embodiments. FIGS. 26A-26B are cross-sectional views of the GAA device 400 after forming the sacrificial dielectric portions 234P to fill the gaps 232. The processes described above with respect to FIGS. 7A and 7B are performed to form the sacrificial dielectric portions 234P.

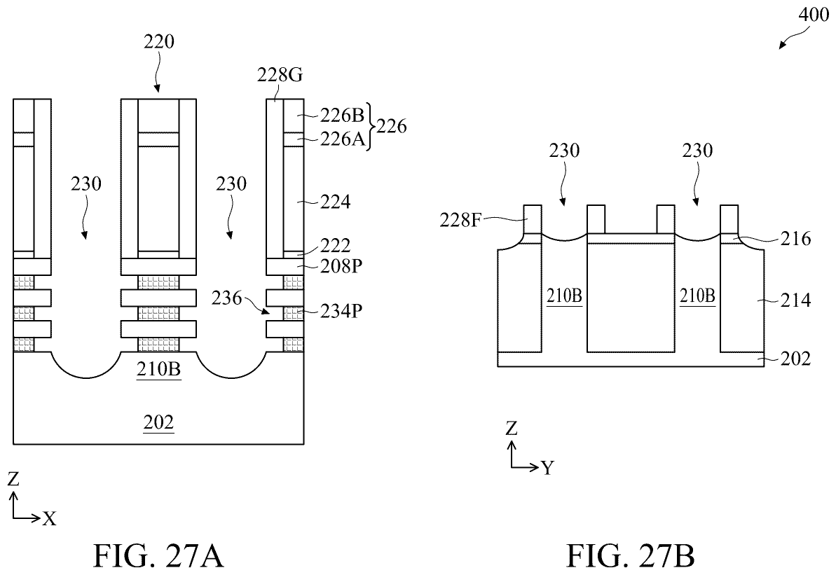

Referring to FIGS. 20 and 27A-27B, the method 300 proceeds to operation 314, where the sacrificial dielectric portions 234P are recessed to form lateral openings 236, in accordance with some embodiments. FIGS. 27A and 27B are cross-sectional views of the GAA device 400 after recessing the sacrificial dielectric portions 234P to form the lateral openings 236. The processes described above with respect to FIGS. 8A and 8B are performed to form the lateral openings 236.

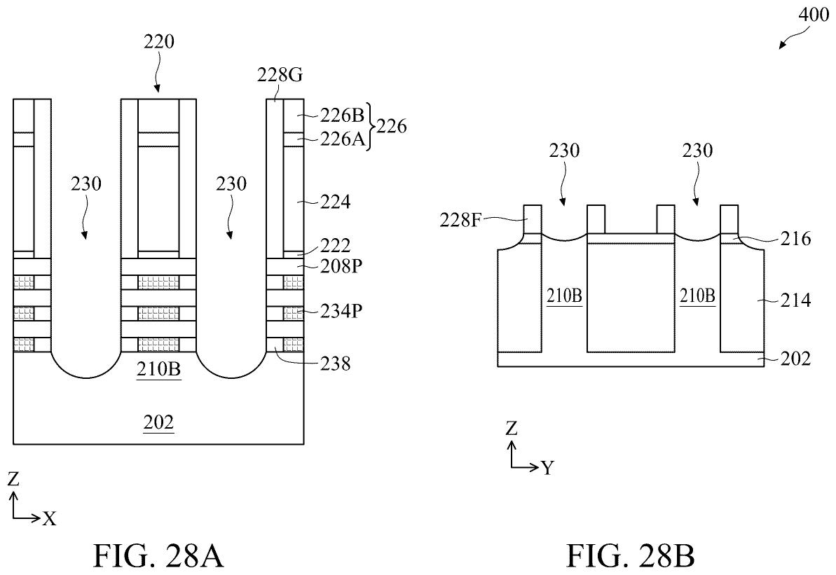

Referring to FIGS. 20 and 28A-28B, the method 300 proceeds to operation 316, where inner spacers 238 are formed in the lateral openings 236, in accordance with some embodiments. FIGS. 28A and 28B are cross-sectional views of the GAA device 400 after forming the inner spacers 238. The processes described above with respect to FIGS. 9A and 9B are performed to form the inner spacers 238.

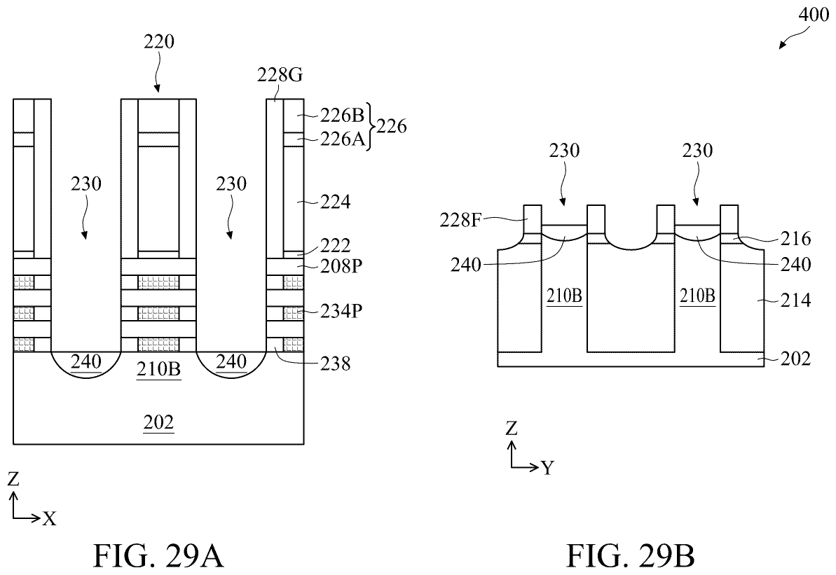

Referring to FIGS. 20 and 29A-29B, the method 300 proceeds to operation 318, where epitaxial semiconductor regions 240 are formed at the bottom of the source/drain trenches 230, in accordance with some embodiments. FIGS. 29A and 29B are cross-sectional views of the GAA device 400 after forming the epitaxial semiconductor regions 240. The processes described above with respect to FIGS. 10A and 10B are performed to form the epitaxial semiconductor regions 240.

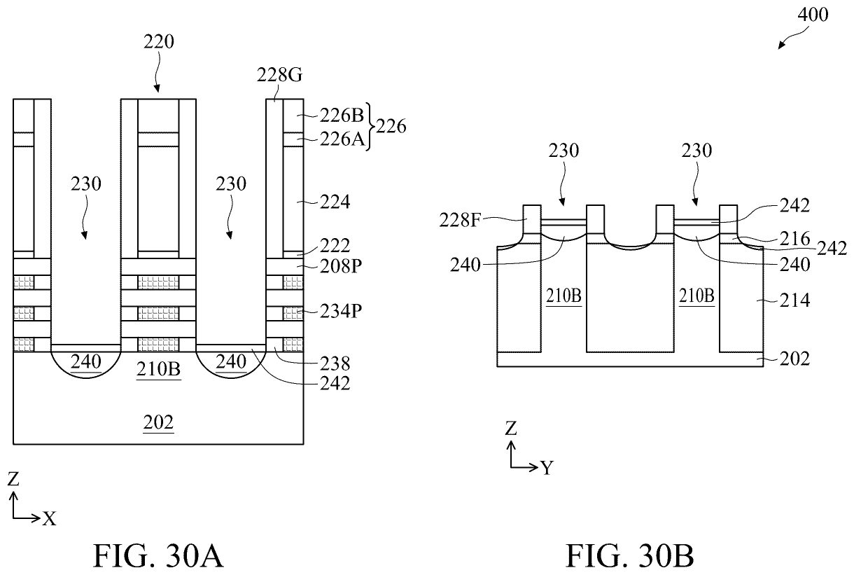

Referring to FIGS. 20 and 30A-30B, the method 300 proceeds to operation 320, where bottom dielectric features 242 are formed on the epitaxial semiconductor regions 240 and the portions of the isolation feature 214 not covered by the fin sidewall spacers 228F, in accordance with some embodiments. FIGS. 30A and 30B are cross-sectional views of the GAA device 400 after forming the bottom dielectric features 242. The processes described above with respect to FIGS. 11A and 11B are performed to form the bottom dielectric features 242.

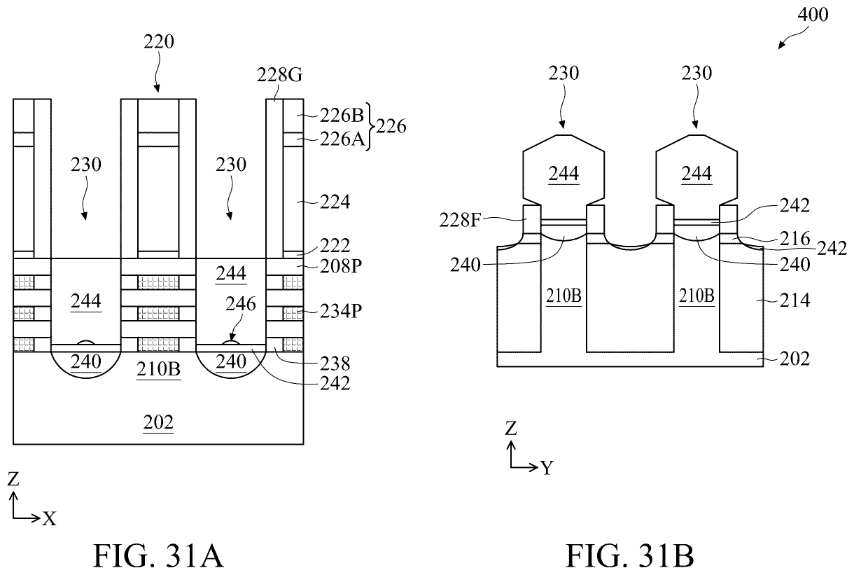

Referring to FIGS. 20 and 31A-31B, the method 300 proceeds to operation 322, where source/drain features 244 are formed in the source/drain trenches 230, in accordance with some embodiments. FIGS. 31A and 31B are cross-sectional views of the GAA device 400 after forming the source/drain features 244. The source/drain features 244 are disposed on opposite sides of the sacrificial dielectric portions 234P and the channel semiconductor portions 208P such that the source/drain features 244 are in contact with the channel semiconductor portions 208P and the inner spacers 238. In some embodiments and as shown in FIG. 31A, top surfaces of the source/drain features are coplanar with the bottom surfaces of the gate sidewall spacers 228G and above the top surfaces of the fin sidewalls spacers 228F. A void 246 may form at the bottom of each source/drain trench 230 between the source/drain feature 244 and the bottom dielectric feature 242. The processes described above with respect to FIGS. 12A and 12B are performed to form the source/drain feature 244.

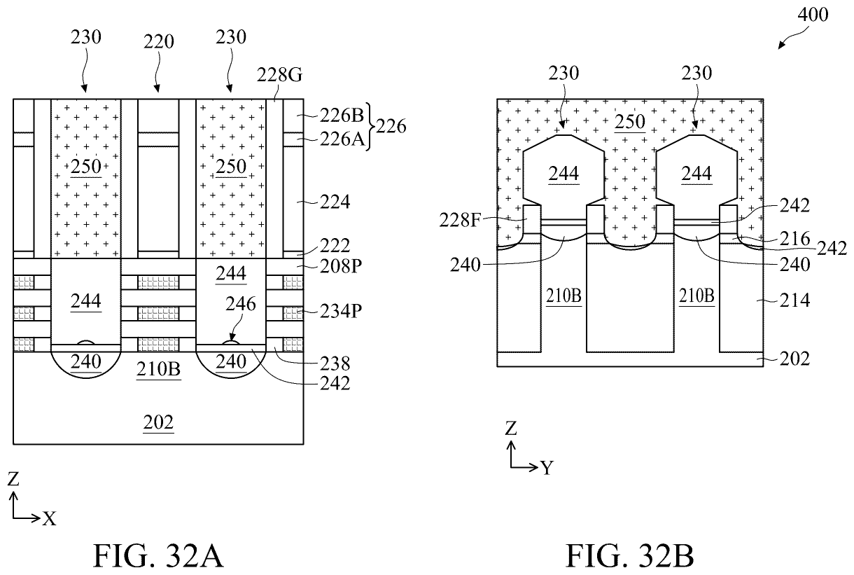

Referring to FIGS. 20 and 32A-32B, the method 300 proceeds to operation 324, where an interlayer dielectric (ILD) layer 250 is formed over the source/drain features 244 and the bottom dielectric features 242, in accordance with some embodiments. FIGS. 32A and 32B are cross-sectional views of the GAA device 400 after forming the ILD layer 250. The processes described above with respect to FIGS. 15A and 15B are performed to form the ILD layer 250.

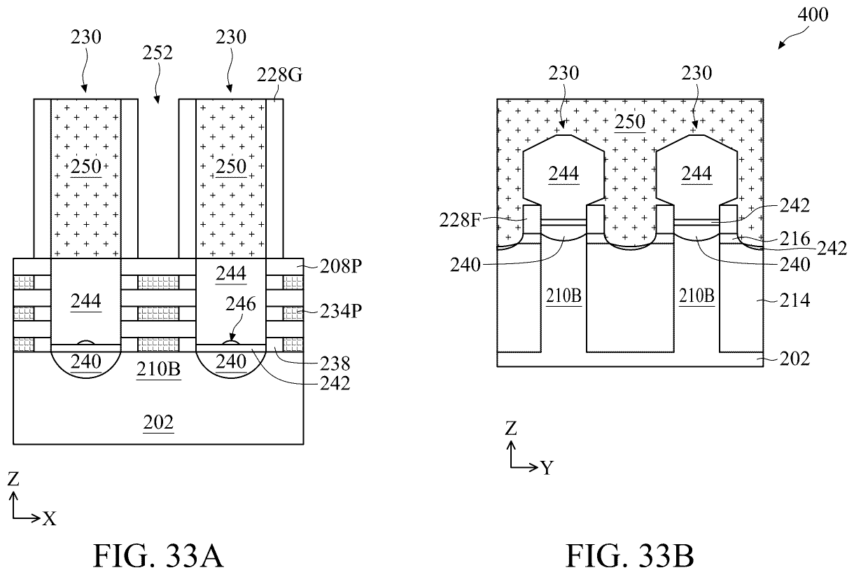

Referring to FIGS. 20 and 33A-33B, the method 300 proceeds to operation 326, where the sacrificial gate structures 220 are removed, in accordance with some embodiments. FIGS. 33A and 33B are cross-sectional views of the GAA device 400 after removing the sacrificial gate structures 220 to form gate trenches 252. The processes described above with respect to FIGS. 16A and 16B are performed to remove the sacrificial gate structures 220.

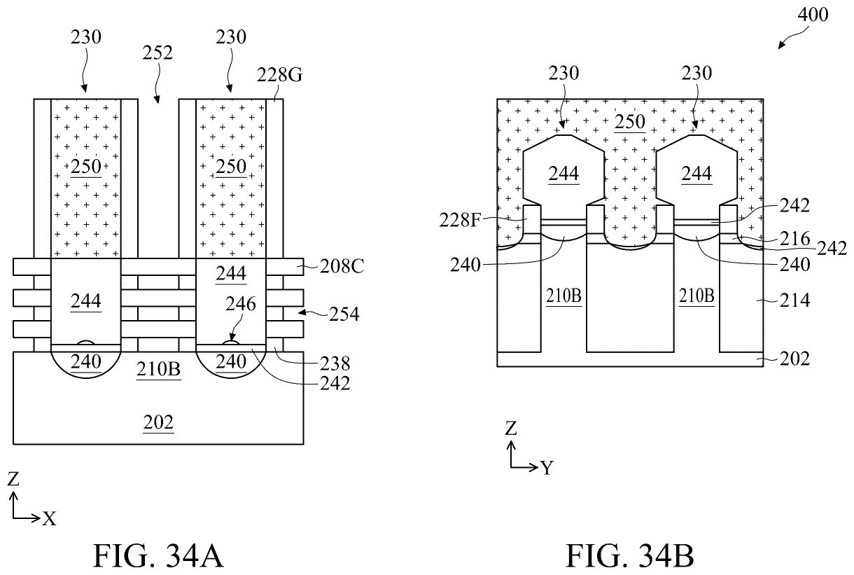

Referring to FIGS. 20 and 34A-34B, the method 300 proceeds to operation 328, where the sacrificial dielectric portions 234P are removed, in accordance with some embodiments. FIGS. 34A and 34B are cross-sectional views of the GAA device 400 after removing the sacrificial dielectric portions 234P. Removal of the sacrificial dielectric portions 234P releases the channel semiconductor portions 208P. Subsequent nanosheet trimming of the channel semiconductor portions 208P forms channel nanostructures 208C and gaps 254 between the channel nanostructures 208C, and between the bottommost channel nanostructure 208C and the base portion 210B. The processes described above with respect to FIGS. 17A and 17B are performed to remove the sacrificial dielectric portions 234P and form the channel nanostructures 208C and the gaps 254.

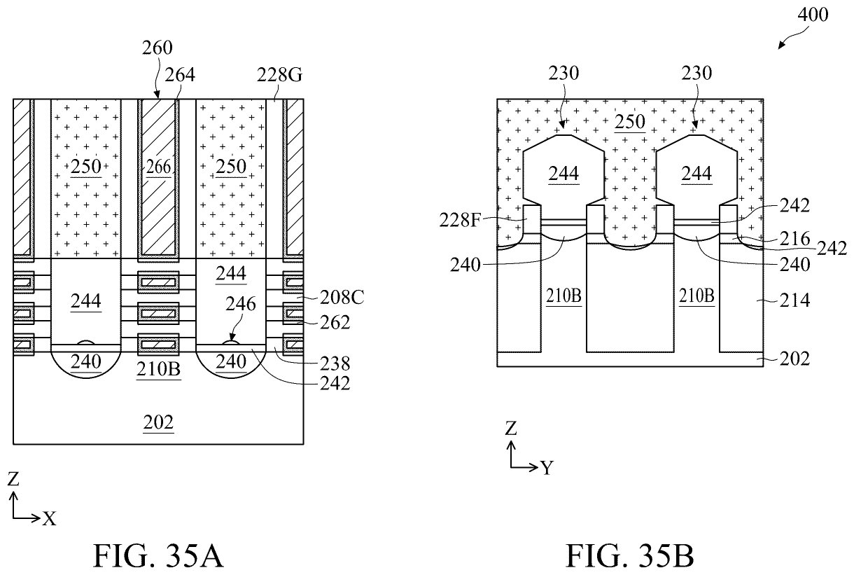

Referring to FIGS. 20 and 35A-35B, the method 300 proceeds to operation 330, where replacement gate structures 260 are formed in the gate trenches 252 and the gaps 254, in accordance with some embodiments. FIGS. 35A and 35B are cross-sectional views of the GAA device 200 after forming the replacement gate structure 260. Each replacement gate structure 260 is deposed over and between the vertically spaced channel nanostructures 208C, respectively and over the base portion 210B. In some embodiments, the replacement gate structure 260 includes an interfacial layer 262, a gate dielectric layer 264, and a gate electrode layer 266. In some embodiments, the replacement gate structure 260 may include a conformal gate work function layer between the gate dielectric layer 264 and the gate electrode layer 266. The processes described above with respect to FIGS. 18A and 18B are performed to form the replacement gate structures 260.

Additional processing may be performed to finish the fabrication of the GAA device 400. For example, gate contact (not illustrated for simplicity) and the source/drain contacts may be formed to electrically couple to the replacement gate structure 260 and the source/drain features 244, respectively. An interconnect structure may then be formed over the source/drain contacts and the gate contact. The interconnect structure may include a plurality of dielectric layers surrounding metallic features, including conductive traces and conductive vias, which form electrical connection between devices on the substrate 202, such as the GAA device 400.

One aspect of this description relates to a method for forming a semiconductor device. The method includes forming, over a top surface of a substrate with a (110) crystal orientation, a plurality of fin structures each comprising alternating channel semiconductor portions and sacrificial dielectric portions, wherein sidewalls of the channel semiconductor portions of adjacent fin structures in the plurality of fin structures of each of the adjacent fin structures are exposed by a source/drain trench, wherein top, sidewall and bottom surfaces of the channel semiconductor portions of the adjacent fin structures have the (110) crystal orientation; depositing an epitaxial semiconductor region at a bottom of the source/drain trench; forming a bottom dielectric feature over the epitaxial semiconductor region; and epitaxially growing a source/drain feature from the sidewall surfaces of the channel semiconductor portions of the adjacent fin structures to fill the source/drain trench.

Another aspect of this description relates to a method for forming a semiconductor device. The method includes forming, over a top surface of a substrate with a (110) crystal orientation, a plurality of fin structures, each of the fin structures including a base portion, alternatively stacked first semiconductor portions and second semiconductor portions over the base portion, and a hard mask portion over the alternatively stacked first and second semiconductor portions; forming a plurality of sacrificial gate structures crossing the fin structures; forming source/drain trenches on opposite sides of the sacrificial gate structures, each of the source/drain trenches extending into the base portion of each of the fin structures; replacing the second semiconductor portions in each of the fin structures with sacrificial dielectric portions; forming epitaxial semiconductor regions at bottoms of the source/drain trenches; depositing bottom dielectric features over the epitaxial semiconductor regions; and forming source/drain features in the source/drain trenches by epitaxially growing a plurality of conformal source/drain epitaxial layers layer-by-layer using sidewalls of the second semiconductor portions as seed layers and epitaxial growing a source/drain epitaxial layer over the conformal source/drain epitaxial layers. The top, sidewall and bottom surfaces of the second semiconductor portions of the plurality of fin structures have the (110) crystal orientation.

Still another aspect of this description relates to a semiconductor device. The semiconductor device includes a substrate having a (110) surface crystal orientation; a first plurality of channel nanostructures over a first region of the substrate and extending along a lengthwise direction; a second plurality of channel nanostructures over a second region of the substrate and extending along the lengthwise direction; a bottom dielectric feature disposed over the substrate between the first plurality of channel nanostructures and the second plurality of channel nanostructures; and a source/drain feature disposed over the bottom dielectric feature and having a first side contacting sidewalls of the first plurality of channel nanostructures and a second side contacting sidewalls of the second plurality of channel nanostructures. The top, bottom and side surfaces of the first and second plurality of channel nanostructures have a (110) crystal orientation, and the source/drain feature comprises multiple conformal source/drain epitaxial semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device, comprising:
forming, over a top surface of a substrate with a (110) crystal orientation, a plurality of fin structures each comprising alternating channel semiconductor portions and sacrificial dielectric portions, wherein sidewalls of the channel semiconductor portions of adjacent fin structures in the plurality of fin structures of each of the adjacent fin structures are exposed by a source/drain trench, wherein top, sidewall and bottom surfaces of the channel semiconductor portions of the adjacent fin structures have the (110) crystal orientation;
depositing an epitaxial semiconductor region at a bottom of the source/drain trench;
forming a bottom dielectric feature over the epitaxial semiconductor region; and
epitaxially growing a source/drain feature from the sidewall surfaces of the channel semiconductor portions of the adjacent fin structures to fill the source/drain trench.

2. The method of claim 1, further comprising:
removing the sacrificial dielectric portions from each fin structure of the plurality of the fin structures to release the channel semiconductor portions; and
forming a gate structure to wrap around the channel semiconductor portions in each fin structure.

3. The method of claim 1, wherein each of the plurality of fin structures further comprises a base portion beneath the alternating channel semiconductor portions and sacrificial dielectric portions, wherein the source/drain trench exposes sidewalls of the base portion.

4. The method of claim 3, wherein depositing the epitaxial semiconductor region at the bottom of the source/drain trench comprises epitaxially growing a semiconductor material from the sidewalls of the base portion and a subsurface of the substrate.

5. The method of claim 4, further comprising epitaxially grown a stack including a plurality of first semiconductor layers and a plurality of second semiconductor layers arranged in an alternate manner over the top surface of the substrate, wherein a top surface of each of the plurality of first semiconductor layers and the plurality of second semiconductor layers has the (110) crystal orientation.

6. The method of claim 5, further comprising patterning the stack and the substrate to form a plurality of stacked structures, wherein each of the plurality of stacked structures comprises the base portion protruding from the subsurface of the substrate and remaining portions of the first and second semiconductor layers.

7. The method of claim 6, further comprising:
forming a plurality of sacrificial gate structures over the plurality of stacked structures; and
forming gate sidewall spacers on sidewalls of the sacrificial gate structures.

8. The method of claim 7, further comprising removing a portion of the plurality of stacked structures between adjacent sacrificial gate structures of the plurality of sacrificial gate structures to form the source/drain trench.

9. The method of claim 8, further comprising:
removing portions of the remaining portions of the second semiconductor layers beneath the plurality of sacrificial gate structures and the gate sidewall spacers, thereby forming gaps between portions of the remaining portions of first semiconductor layers beneath the plurality of sacrificial gate structures, wherein the portions of the remaining portions of first semiconductor layers in each of the plurality of stacked structures constitute the channel semiconductor portions; and
forming the sacrificial dielectric portions in the gaps between the channel semiconductor portions, wherein the sacrificial dielectric portions are laterally surrounded by inner spacers.

10. The method of claim 9, further comprising forming the inner spacers that comprises:
laterally etching the sacrificial dielectric portions to form openings; and
filling the openings with a dielectric material.

11. A method for forming a semiconductor device, comprising:
forming, over a top surface of a substrate with a (110) crystal orientation, a plurality of fin structures, each of the fin structures including a base portion, alternatively stacked first semiconductor portions and second semiconductor portions over the base portion, and a hard mask portion over the alternatively stacked first and second semiconductor portions;
forming a plurality of sacrificial gate structures crossing the fin structures;
forming source/drain trenches on opposite sides of the sacrificial gate structures, each of the source/drain trenches extending into the base portion of each of the fin structures;
replacing the second semiconductor portions in each of the fin structures with sacrificial dielectric portions;
forming epitaxial semiconductor regions at bottoms of the source/drain trenches;
depositing bottom dielectric features over the epitaxial semiconductor regions; and
forming source/drain features in the source/drain trenches by epitaxially growing a plurality of conformal source/drain epitaxial layers layer-by-layer using sidewalls of the second semiconductor portions as seed layers and epitaxial growing a source/drain epitaxial layer over the conformal source/drain epitaxial layers, wherein top, sidewall and bottom surfaces of the second semiconductor portions of the plurality of fin structures have the (110) crystal orientation.

12. The method of claim 11, further comprising forming an inter-level dielectric (ILD) layer over the source/drain features, the ILD layer laterally surrounding the sacrificial gate structures.

13. The method of claim 12, further comprising removing the sacrificial gate structures to form gate trenches.

14. The method of claim 13, further comprising removing the sacrificial dielectric portions to release the first semiconductor portions.

15. The method of claim 14, further comprising forming a gate structure in a corresponding gate trench and spaces between corresponding first semiconductor protons.

16. A semiconductor device, comprising:
a substrate having a (110) surface crystal orientation;
a first plurality of channel nanostructures over a first region of the substrate and extending along a lengthwise direction;
a second plurality of channel nanostructures over a second region of the substrate and extending along the lengthwise direction;
a bottom dielectric feature disposed over the substrate between the first plurality of channel nanostructures and the second plurality of channel nanostructures; and
a source/drain feature disposed over the bottom dielectric feature and having a first side contacting sidewalls of the first plurality of channel nanostructures and a second side contacting sidewalls of the second plurality of channel nanostructures,
wherein the top, bottom and side surfaces of the first and second plurality of channel nanostructures have a (110) crystal orientation
wherein the source/drain feature comprises multiple conformal source/drain epitaxial semiconductor layers.

17. The semiconductor device of claim 16, wherein a void is present between the source/drain feature and the bottom dielectric feature.

18. The semiconductor device of claim 16, further comprising a hard mask portion disposed over each of the first plurality of channel nanostructures and the second plurality of channel nanostructures.

19. The semiconductor device of claim 16, wherein the source/drain feature further comprises a source/drain epitaxial layer over the multiple conformal source/drain epitaxial semiconductor layers.

20. The semiconductor device of claim 16, further comprising:
a first plurality of inner spacers interleaving the first plurality of channel nanostructures; and
a second plurality of inner spacers interleaving the second plurality of channel nanostructures,
wherein the source/drain feature contacts sidewalls of the first plurality of inner spacers and sidewalls of the second plurality of inner spacers.
